(19) United States
(12) Patent Application Publication
(10) Pub. No.: US 2026/0282463 A1
(43) Pub. Date: Sep. 17, 2026

(54) METAL OXIDE SEMICONDUCTOR FIELD EFFECT TRANSISTORS (MOSFET) WIH BOTTOM P-WELLS AND DEEP P-WELLS

(71) Applicant: The Research Foundation for The State University of New York, Albany, NY (US)

(72) Inventors: Woongje SUNG, Niskayuna, NY (US); Dongyoung KIM, Albany, NY (US); Seung Yup JANG, Cohoes, NY (US)

(21) Appl. No.: 18/877,718

(22) PCT Filed: Jun. 29, 2023
(86) PCT No.: PCT/US2023/069379

§ 371 Date: Dec. 20, 2024

Related U.S. Application Data
(60) Provisional application No. 63/357,718, filed on Jul. 1, 2022.

(51) Int. Cl. H10D 62/10; H10D 30/01; H10D 30/66; H10D 62/00; H10D 62/832

(52) U.S. Cl. CPC H10D 62/109; H10D 30/0297; H10D 30/668; H10D 62/054; H10D 62/8325

(57) ABSTRACT

A field effect transistor including a substrate having an upper surface thereof. An epitaxial layer including n-type is material disposed over the upper surface of the substrate. A P-well including P-type material is diffused within an upper portion of the n-type material of the epitaxial layer. At least one of a first deep P-well or a bottom P-well is formed within the epitaxial layer. The first deep P-well includes P-type material formed within the epitaxial layer, beneath and adjacent to the P-well. The bottom P-well is formed within a bottom portion of the epitaxial layer. An N-type region is disposed at least partially over the P-well. An oxide region is formed within at least a portion of the N-type region, the P-well, and the epitaxial layer. The oxide region is further partially disposed over the N-type region. A gate is formed within the oxide region.

### CROSS REFERENCE TO RELATED APPLICATIONS

This application is a non-provisional of, and claims the benefit of the filing date of, U.S. provisional application 63/357,718, filed Jul. 1, 2022, entitled, “METAL OXIDE SEMICONDUCTOR FIELD EFFECT TRANSISTORS (MOSFET) INCLUDING TRENCH STRUCTURES WITH BOTTOM P-WELLS AND METHODS FOR THEIR FABRICATION,” the contents of which are incorporated herein by reference.

### BACKGROUND OF THE INVENTION

### Field of the Invention

The disclosure relates generally to semiconductor devices, and more particularly, to Metal Oxide Semiconductor Field Effect Transistors (MOSFET) including new trench structures for improving MOSFET static performances, reliability, and ruggedness and methods of forming the same.

### Description of the Related Art

Silicon Carbide MOSFETS have problems related to their reliability and ruggedness. At the junction between the P-type and N-type portions of this type of MOSFET, common with structures already present in the art, there are high electric fields that lead to these MOSFETS having shorter short-circuit withstand time. Prior solutions to reducing these electric fields to enhance short-circuit ruggedness of MOSFETS include lowering channel/JFET density, source doping reduction, or lowering gate voltage. However, these solutions lead to an unideal tradeoff by causing increases in specific on-resistance of MOSFETS. To improve the tradeoff between short-circuit withstand time and SiC MOSFET's on-resistance, a MOSFET including new trench structures and methods of making the same is provided herein.

### BRIEF DESCRIPTION

The new trench structures disclosed herein enable improvements in the methods of forming SIC MOSFETs with bottom P-wells. The new trench structures enable the doping of the bottom P-well prior to etching of the trench, enabling better control of the critical dimensions of the bottom P-well such that the bottom P-well can be structured such that there is a reduction in the electric field near the trench corner. This stepwise ordering of doping a bottom P-well prior to etching a trench also requires lower implantation energy and does not require the trench to be etched with a hard mask. The stepwise ordering also eliminates the concern of implanting the sidewall of the trench. By using channeling implantation, the process does not require high energy implantations. The new trench structures therefore improve MOSFET static performances, reliability, and ruggedness with a reduced complexity in processing.

The present invention therefore improves overall reliability and ruggedness of SIC MOSFETs. The structures herein reduce the electric field at the corner of the trench, which also improves short circuit withstand time. The structure also offers a much less complicated processing scheme by using a channeling implantation instead of using multi-MeV (high energy) implants.

A first aspect of the disclosure provides for a first field effect transistor with a new trench structure, including: a substrate; an epitaxial layer disposed over the substrate; a P-well formed within the epitaxial layer; a first deep P-well formed beneath and adjacent to the P-well; a second deep P-well formed beneath and adjacent to the P-well, wherein the second deep P-well is positioned opposite the first deep P-well; an N-type region disposed at least partially over the P-well; at least one P-type region disposed over a portion of the P-well and adjacent to the N-type region; an oxide region formed within at least a portion of the N-type region, the P-well, and the epitaxial layer and partially disposed over the N-type region; a gate formed within the oxide region; a source region disposed over the oxide region, N-type region, and the P-well; and a drain contact disposed beneath the substrate.

A second aspect of the disclosure provides for a field effect transistor with another new trench structure, including: a substrate; an epitaxial layer disposed over the substrate; a bottom P-well formed within the epitaxial layer; a P-well disposed over the epitaxial layer; an N-type region disposed at least partially over the second portion of the P-well; at least one P-type region disposed over a portion of the P-well and adjacent to the N-type region; optionally a first deep P-well adjacent to the P-well and the bottom P-well, wherein the first deep P-well includes at least one distinct area of the first deep P-well, each of the at least one distinct areas further comprising a respective doping concentration; optionally a second deep P-well adjacent to the P-well and the bottom P-well, and positioned opposite the first deep P-well, wherein the second deep P-well includes at least one distinct area, each of the at least one distinct areas of the second deep P-well further comprising a respective doping concentration; an oxide region formed within at least a portion of the N-type region, the P-well, the epitaxial layer, and the bottom P-well and partially disposed over the N-type region; a gate formed within the oxide region, a source region disposed over the oxide region, N-type region, and the P-well; and a drain contact disposed beneath the substrate.

A third aspect of this disclosure provides for a field effect transistor with another new trench structure, including: a substrate; an epitaxial layer disposed over the substrate; a bottom P-well formed within the epitaxial layer; a P-well disposed over the epitaxial layer; an N-type region disposed at least partially over the second portion of the P-well; at least one P-type region disposed over a portion of the P-well and adjacent to the N-type region; an oxide region formed within at least a portion of the N-type region, the P-well, the epitaxial layer, and the bottom P-well and partially disposed over the N-type region; a gate formed within the oxide region; a source region disposed over the oxide region, N-type region, and the P-well; and a drain contact disposed beneath the substrate.

A fourth aspect of the disclosure provides a method of forming a field effect transistor with another new trench structure, including: a substrate; an epitaxial layer disposed over the substrate; a bottom P-well formed within the epitaxial layer; a P-well disposed over the epitaxial layer; an N-type region disposed at least partially over the second portion of the P-well; at least one P-type region disposed over a portion of the P-well and adjacent to the N-type region; a first deep P-well adjacent to the P-well and the bottom P-well; a second deep P-well adjacent to the P-well and the bottom P-well, wherein the second deep P-well is positioned opposite the first deep P-well; an oxide region formed within at least a portion of the N-type region, the P-well, the epitaxial layer, and the bottom P-well and partially disposed over the N-type region; a gate formed within the oxide region; a source region disposed over the oxide region, N-type region, and the P-well; and a drain contact disposed beneath the substrate.

A fifth aspect of the disclosure provides a method of forming a field effect transistor with the first new trench structure. This method including: disposing an epitaxial layer disposed over a substrate; doping a portion of the epitaxial layer to form a bottom P-well formed within the epitaxial layer; doping a portion of the epitaxial layer to form a P-well a distance above the bottom P-well; doping a portion of the epitaxial layer to form an N-type region disposed at least partially over the P-well; doping a portion of the epitaxial layer to form at least one P-type region disposed over a portion of the P-well and adjacent to the N-type region; forming a trench region within at least a portion of the N-type region, the P-well, the epitaxial layer, and the bottom P-well; disposing an oxide region within the trench region and partially disposed over the N-type region; forming a gate within a portion of the oxide region; depositing and patterning an interlayer dielectric material to form a source region wherein the source region is disposed over the oxide region, at least a portion of the N-type region, and the P-well; and disposing a drain contact beneath the substrate.

The illustrative aspects of the present disclosure are designed to solve the problems herein described and/or problems not discussed.

### BRIEF DESCRIPTION OF THE DRAWINGS

FIG. 1 shows a cross-sectional view of a Metal Oxide Semiconductor Field Effect Transistors (MOSFET), according to a first embodiment of a first trench structure of the disclosure.

FIG. 2 shows a cross-sectional view of a portion of MOSFET 100, according to an additional second embodiment of a second trench structure of the disclosure.

FIG. 3 shows a cross-sectional view of a portion of MOSFET 100, according to an additional third embodiment of a third trench structure of the disclosure.

FIG. 4 is a cross-sectional view of the MOSFET of FIG. 1 illustrating the growing of the epitaxial layer on the substrate.

FIG. 5 is a cross-sectional view of the MOSFET of FIG. 1 illustrating the doping of the epitaxial layer to form the P-well.

FIG. 6 illustrates the deep P-well with a first distinction concentration.

FIG. 7 illustrates the first ion concentration directed toward the epitaxial layer.

FIG. 8 is showing doping the deep P-well with a second distinct ion concentration.

FIG. 9 is showing doping the deep P-well with a third distinct ion concentration.

FIG. 10 is showing doping the deep P-well with a fourth distinct ion concentration.

FIG. 11 is showing doping the epitaxial layer disposed above the deep P-well to form the P-type region.

FIG. 12 is showing doping the epitaxial layer disposed above the P-well and adjacent to the P-type region to form the N-type region.

FIG. 13 is illustrating etching a trench and forming the oxide region within the trench.

FIG. 14 is illustrating forming a gate within the oxide region.

FIG. 15 is illustrating forming a drain contract disposed beneath the substrate and forming a source region disposed above the gate and the oxide region.

FIG. 16 is a cross-sectional view of the MOSFET of FIG. 2, illustrating growing the epitaxial layer on the substrate.

FIG. 17 is illustrating doping the epitaxial layer to form the bottom P-well with a first distinction concentration.

FIG. 18 is illustrating doping the epitaxial layer to form the bottom P-well with a second distinction concentration.

FIG. 19 is illustrating doping the epitaxial layer to form the bottom P-well with a third distinction concentration.

FIG. 20 is illustrating doping the epitaxial layer to form the bottom P-well with a fourth distinction concentration.

FIG. 21 is illustrating doping the epitaxial layer to form the P-well disposed over the epitaxial layer.

FIG. 22 is illustrating doping the P-well to form the P-type region disposed over the epitaxial layer.

FIG. 23 is showing doping the epitaxial layer disposed above the P-well and adjacent to the P-type region to form the N-type region.

FIG. 24 is illustrating etching a trench and forming the oxide region within the trench.

FIG. 25 is illustrating forming a gate within the oxide region.

FIG. 26 is illustrating forming a drain contract disposed beneath the substrate and forming a source region disposed above the gate and the oxide region.

FIG. 27 is a cross-sectional view of the MOSFET of FIG. 3, illustrating growing the epitaxial layer on the substrate.

FIG. 28 is illustrating doping the epitaxial layer to form the bottom P-well with at least one ion concentrations.

FIG. 29 is illustrating doping the epitaxial layer to form the P-well disposed over the epitaxial layer.

FIG. 30 is illustrating doping the epitaxial layer to form the deep P-well with at least one distinction concentration.

FIG. 31 is illustrating doping the P-well to form the P-type region disposed over the deep P-well.

FIG. 32 is showing doping the epitaxial layer disposed above the P-well and adjacent to the P-type region to form the N-type region.

FIG. 33 is illustrating etching a trench and forming the oxide region within the trench.

FIG. 34 is illustrating forming a gate within the oxide region.

FIG. 35 is illustrating forming a drain contract disposed beneath the substrate and forming a source region disposed above the gate and the oxide region.

FIG. 36 is a cross-sectional view of the MOSFET of FIG. 3 at an early stage of formation, illustrating an alternative method of forming the MOSFET of FIG. 3, wherein the P-well, the P-type region, the N-source and ultimately the gate are formed prior to forming the bottom P-well.

FIG. 37 is a cross-sectional view of the MOSFET of FIG. 36, illustrating the etching of a trench into the epitaxial layer.

FIG. 38 is a cross-sectional view of the MOSFET of FIG. 37, illustrating the implantation of the bottom P-well.

FIG. 39 is a cross-sectional view of the MOSFET of FIG. 38, illustrating the formation of a gate oxide layer (a portion of the oxide layer) and the gate within the trench.

FIG. 40 is a cross-sectional view of the MOSFET of FIG. 39, illustrating the formation of the oxide layer over the gate.

FIG. 41A is a cross-sectional view of the MOSFET of any of FIGS. 1-3, illustrating the formation of the substrate layer and epitaxial layer being formed with a predetermined tilt angle in order to form a higher quality crystalline lattice in the epitaxial layer.

FIG. 41B is a cross-sectional view of the MOSFET of FIG. 41A, wherein the substrate has been tilted to the predetermined tilt angle to align the Miller Index 0001 lattice plane of crystals of the epitaxial layer with an ion implantation beam, in order to perform a channeling implantation process on the epitaxial layer.

FIG. 42 is a cross-sectional view of an oxide hardmask disposed over a MOSFET illustrating the minimum critical dimensions for various implantation energies, based on a fixed aspect ratio between the oxide hardmask thickness and the minimum critical dimension.

FIG. 43 is a cross-sectional view of the MOSFET of FIG. 3, wherein the bottom P-well and the deep P-wells were implanted with 1 MeV implantation energy, using a channeling implantation process.

FIG. 44 is a cross-sectional view of the MOSFET of FIG. 3, wherein the bottom P-well and the deep P-wells were implanted with 1 MeV implantation energy, using a random (or conventional) implantation process.

FIG. 45 is a cross-sectional view of the MOSFET of FIG. 3, wherein the bottom P-well and the deep P-wells were implanted with 4 MeV implantation energy, using a random (or conventional) implantation process.

### DETAILED DESCRIPTION OF THE INVENTION

Certain examples will now be described to provide an overall understanding of the principles of the structure, function, manufacture, and use of the methods, systems, and devices disclosed herein. One or more examples are illustrated in the accompanying drawings. Those skilled in the art will understand that the methods, systems, and devices specifically described herein and illustrated in the accompanying drawings are non-limiting examples and that the scope of the present disclosure is defined solely by the claims. The features illustrated or described in connection with one example may be combined with the features of other examples. Such modifications and variations are intended to be included within the scope of the present disclosure.

The terms “significantly”, “substantially”, “approximately”, “about”, “relatively,” or other such similar terms that may be used throughout this disclosure, including the claims, are used to describe and account for small fluctuations, such as due to variations in processing from a reference or parameter. Such small fluctuations include a zero fluctuation from the reference or parameter as well. For example, they can refer to less than or equal to #10%, such as less than or equal to +5%, such as less than or equal to +2%, such as less than or equal to +1%, such as less than or equal to +0.5%, such as less than or equal to +0.2%, such as less than or equal to #0.1%, such as less than or equal to +0.05%.

As an initial matter, in order to clearly describe the current disclosure, it will become necessary to select certain terminology when referring to and describing relevant components within the disclosure. When doing this, if possible, common industry terminology will be used and employed in a manner consistent with its accepted meaning. Unless otherwise stated, such terminology should be given a broad interpretation consistent with the context of the present application and the scope of the appended claims. Those of ordinary skill in the art will appreciate that often a particular component may be referred to using several different or overlapping terms. What may be described herein as being a single part may include and be referenced in another context as consisting of multiple components. Alternatively, what may be described herein as including multiple components may be referred to elsewhere as a single part.

As discussed herein, the disclosure relates generally to semiconductor devices, and more particularly, to Metal Oxide Semiconductor Field Effect Transistors (MOSFET) including trench structures with bottom p-wells and methods of forming the same.

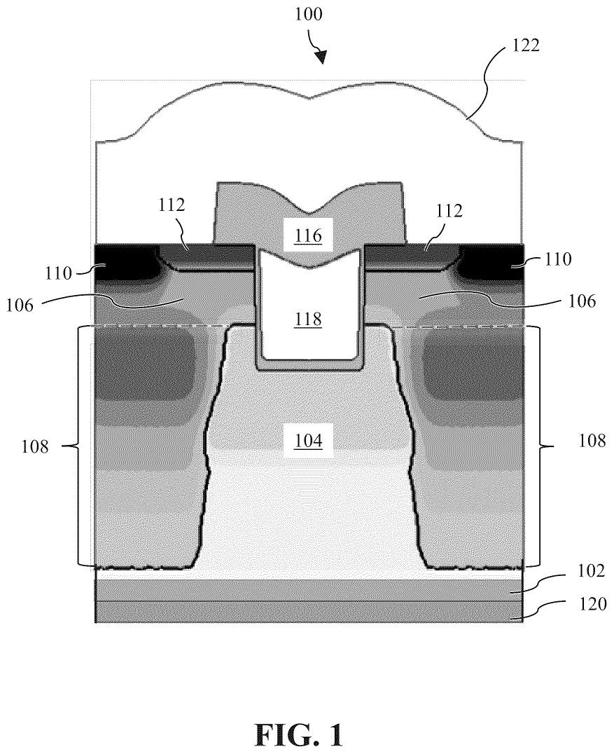

These and other embodiments are discussed below with reference to FIGS. 1-45. However, those skilled in the art will readily appreciate that the detailed description given herein with respect to these Figures is for explanatory purposes only and should not be construed as limiting.

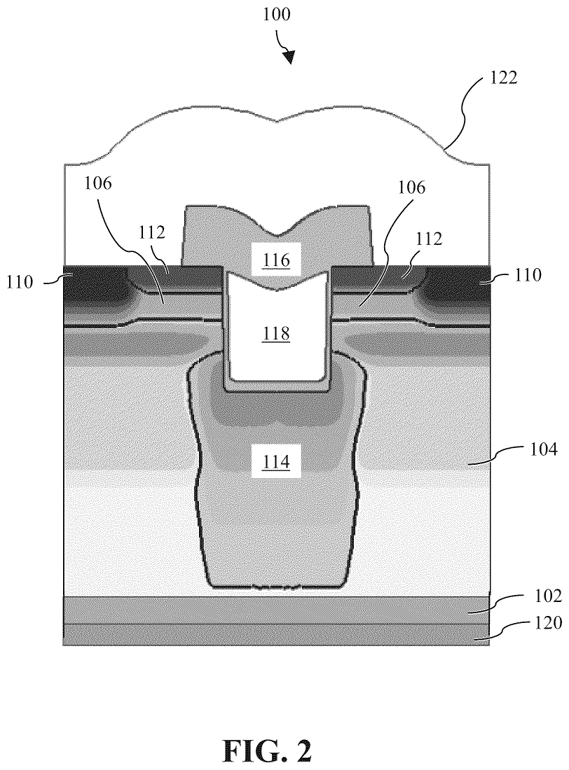

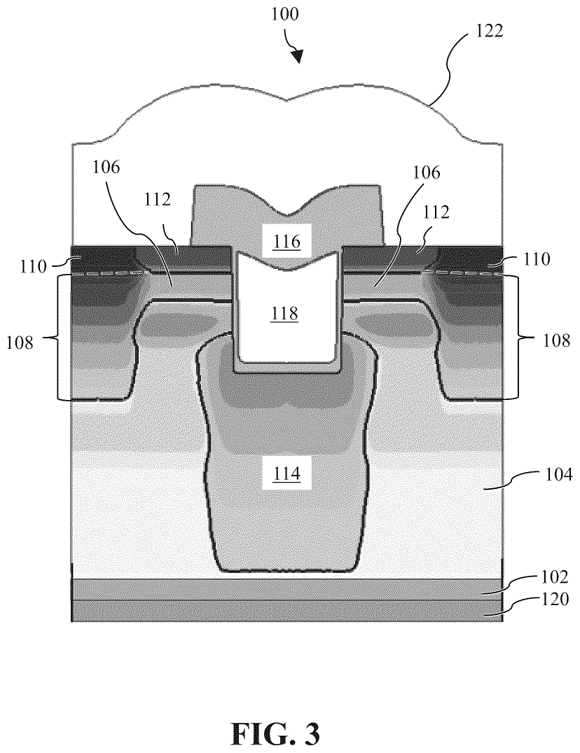

FIGS. 1, 2 and 3 show cross-sectional views of a portion of a semiconductor device. More specifically, FIG. 1 shows a cross-sectional view of a Metal Oxide Semiconductor Field Effect Transistors (MOSFET) 100, FIG. 2 shows a cross-sectional view of MOSFET 100, and FIG. 3 shows a cross-sectional view of MOSFET 100. MOSFET 100 shown in FIG. 1 is a silicone carbide (SIC) MOSFET, but, alternatively, any other suitable MOSFET that may implement the structure described herein can be used. Similarly, MOSFET 100 shown in FIG. 2 and MOSFET 100 shown in FIG. 3 may be a silicone carbide (SIC) MOSFET, or any other suitable MOSFET that may implement the structured described herein.

As shown in FIGS. 1, 2 and 3, MOSFET 100 may include a substrate (or substrate layer) 102. The substrate may include or form a base layer of MOSFET 100 that may be formed as a semiconducting material and/or may be formed from any suitable material or material composition that includes semiconducting properties/characteristic. For example, substrate may be formed from indium phosphide (InP) or Indium gallium arsenide (InGaAs). In other non-limiting examples substrate can include without limitation, substances consisting essentially of one or more compound semiconductors. Substrate can be provided as a bulk substrate or as part of a silicon-on-insulator (SOI) wafer. Additionally, or alternatively, substrate may be formed from, for example, silicon (Si), silicon carbide (SiC), germanium (Ge), germanium oxide (GeO), cadmium zinc telluride (CdZnTe), gallium nitride (GaN), or gallium arsenide (GaAs). Furthermore, substrate layer may be fabricated as a layer of semiconductor material, substances or materials consisting essentially of one or more compound semiconductors having a composition defined by the formula AlX1GaX2InX3AsY1PY2NY3SbY4, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substances can include II-VI compound semiconductors having a composition ZnA1CdA2SeBITeB2, where A1, A2, B1, and B2 are relative proportions each greater than or equal to zero and A1+A2+B1+B2=1 (1 being a total mole quantity).

MOSFET 100 shown in FIGS. 1, 2, and 3 includes an epitaxial layer 104. Epitaxial layer 104 may be disposed over substrate 102. More specifically, epitaxial layer 104 may be disposed, formed, positioned over, and/or directly contact substrate 102. Epitaxial layer 104 may be included within MOSFET 100 to substantially block high voltages and/or prevent leakage from other device layers of MOSFET 100 during operation, as discussed herein. Epitaxial layer 104 may be formed from any suitable material or material composition that may prevent leakage and/or provide resistive properties/characteristics. For example, epitaxial layer 104 may be formed from silicon carbine (SiC), Galium nitride (GaN), gallium (III) oxide (Ga₂O₃), aluminum nitride (AlN), and/or any other suitable semiconductor material (e.g., wide bandgap materials).

MOSFET 100 shown in FIGS. 1, 2 and 3 may also include a P-well 106. P-well 106 may be disposed within epitaxial layer 104. P-well 106 may be formed, disposed, and/or positioned over a portion or section of epitaxial layer 104. P-well 106 may be formed from any suitable material or composition of material that may include substantially conductive properties/characteristics. P-well may extend into epitaxial layer 104 a predetermined depth (D) from an oxide region (or oxide layer) of MOSFET 100. For example, P-well 106 is typically in a depth of as 0.5 μm to 1 μm.

MOSFET 100 shown in FIGS. 1 and 3 may also include at least one deep P-well 108. More specifically, MOSFET 100 may include a first deep P-well 108 and a second deep P-well 108. Deep P-well 108 may be formed directly within and/or may extend partially through epitaxial layer 104. In the non-limiting example, and as shown in FIG. 1, two distinct deep P-wells 108 may be formed and/or positioned on either side of epitaxial layer 104, and first deep P-well 108 may be positioned opposite second deep P-well 108 within epitaxial layer 104. Deep P-well 108 of MOSFET 100 may be substantially conductive and may carry, receive, and/or flow an electrical current to distinct portions, components, and/or devices of MOSFET 100, as discussed herein. As such, deep P-well 108 may be formed from any suitable material or composition of material that may include substantially conductive properties/characteristics. For example, and as discussed herein, deep P-well 108 may be formed by doping materials formed within MOSFET 100 (e.g., epitaxial layer 104) via channeling implantation.

It should be noted the distance of the layers as well as their thickness in the drawings are not shown to scale. For example, P-well 108, implanted at a reasonable energy such as ~<400 keV, could be as deep as 2.5 μm. Thus, P-well 108 could almost touch substrate102, but in general, the epitaxial layer 104 would be greater than 6 μm for greater than 600V rated devices.

In the non-limiting example shown in FIG. 1 and FIG. 3, deep P-well 108 may include at least one distinct area. More specifically, and with reference to FIGS. 1 and 2, deep-well may include four distinct portions. More specifically, and with reference to FIG. 1 and FIGS. 7-10, deep P-well 108 of MOSFET 100 may include a first area 124, a second area 126, a third area 128, and a fourth area 130. First area 124 may be disposed directly over epitaxial layer 104. More specifically, first area 124 of deep P-well 108 may be formed, disposed, and/or positioned over a portion or section of epitaxial layer 104. The section of epitaxial layer 104 may be positioned between and/or may separate first area 124 of deep P-well 108 and substrate 102. First area 124 of deep P-well 108 may include a first doping concentration (DC1). That is, and as discussed herein, first portion 124 of deep P-well 108 may be formed by performing a doping process or technique, for example channeling implantation, on a portion of epitaxial layer 104. First portion 124 may be formed by doping epitaxial layer 104 with a first or predetermined ion concentration under first or predetermined operational parameters. The ion concentration and/or operational parameters may determine characteristics of first portion 124. For example, and as shown in FIG. 1, first portion 124 of deep P-well 108 may extend into epitaxial layer 104 a predetermined depth (D).

Second area 126 of deep P-well 108 may be disposed directly over first area 124. More specifically, second area 126 of deep P-well 108 may be formed, disposed, and/or positioned directly over first area 124. Similar to first aera 124, second area 126 of deep P-well 108 may include a second doping concentration (DC2). Second doping concentration (DC2) may be distinct from first doping concentration (DC1) of first area 124. For example, the first doping concentration (DC1) of first area 124 may be less than the second doping concentration (DC2) of second area 126. As discussed herein, second area 126 of deep P-well 108 may be formed by performing a doping process or technique, for example channeling implantation, on a portion of epitaxial layer 104. Second area 126 may be formed by doping a portion of epitaxial layer 104 formed above first area 124 with a second or predetermined ion concentration under second or predetermined operational parameters. The ion concentration and/or operational parameters may determine characteristics of second area 126. In a non-limiting example, the second doping concentration of second area 126 is between approximately 1.0×10¹⁷ atoms per cubic cm (atoms/cm³) and approximately 5.0×10¹⁸ atoms per cubic cm (atoms/cm³).

Third area 128 of deep P-well 108 may be disposed directly over second area 126. More specifically, third area 128 of deep P-well 108 may be formed, disposed, and/or positioned directly over second area 126. Similar to second area 126, third area 128 of deep P-well 108 may include a third doping concentration (DC3). Third doping concentration (DC3) may be distinct from second doping concentration (DC2) of second area 126. For example, the second doping concentration (DC2) of second area 126 may be less than the third doping concentration (DC3) of third area 128. As discussed herein, third area 128 of deep P-well 108 may be formed by performing a doping process or technique, for example channeling implantation, on a portion of epitaxial layer 104. Third area 128 may be formed by doping a portion of epitaxial layer 104 formed above second area 126 with a third or predetermined ion concentration under third or predetermined operational parameters. The ion concentration and/or operational parameters may determine characteristics of third area 128.

Fourth area 130 of deep P-well 108 may be disposed directly over third area 128. More specifically, fourth area 130 of deep P-well 108 may be formed, disposed, and/or positioned directly over third area 128. Similar to third area 128, fourth area 130 of deep P-well 108 may include a fourth doping concentration (DC4). Fourth doping concentration (DC4) may be distinct from third doping concentration (DC3) of third area 128. For example, the fourth doping concentration (DC4) of fourth area 130 may be less than the third doping concentration (DC3) of third area 128. As discussed herein, fourth area 130 of deep P-well 108 may be formed by performing a doping process or technique, for example channeling implantation, on a portion of epitaxial layer 104. Fourth area 130 may be formed by doping a portion of epitaxial layer 104 formed above third area 128 with a fourth or predetermined ion concentration under third or predetermined operational parameters. The ion concentration and/or operational parameters may determine characteristics of fourth area 130.

MOSFET 100 may also include a P-type region 110. P-type region 110 may be disposed at least partially over deep P-well 108 of MOSFET 100. More specifically, and as shown in the non-limiting example of FIG. 1, P-type region 110 may be disposed at least partially over first deep P-well 108, and P-type region 110 may be disposed at least partially over second deep P-well 108. P-type region 110 of MOSFET 100 may be substantially conductive and may carry, receive, and/or flow an electrical current within MOSFET 100, as discussed herein. As such, P-type region 110 may be formed from any suitable material or composition of material that may include substantially conductive properties/characteristics. For example, P-type region 110 may be formed using a doping technique (e.g., channeling implantation) on the materials formed within MOSFET 100 (e.g., epitaxial layer 104).

MOSFET 100 may also include an N-source (or N-type region) 112. N-source 112 may be disposed at least partially over P-well 106 of MOSFET 100. More specifically, and as shown in the non-limiting example of FIGS. 1, 2 and 3, N-source 112 may be disposed at least partially over and/or at least partially within a portion of P-well 106 and a portion of P-type region 110. N-source 112 of MOSFET 100 may be substantially conductive and may carry, receive, and/or flow an electrical current within MOSFET 100, as discussed herein. As such, N-source 112 may be formed from any suitable material or composition of material that may include substantially conductive properties/characteristics. For example, and similar to P-well 106, N-source 112 may be formed using a doping technique (e.g., ion implantation or channeling implantation) on the materials formed within MOSFET 100 (e.g., epitaxial layer 104).

An oxide region (or oxide layer) 116 may be formed over various portions, components, and/or devices of MOSFET 100. More specifically, and as shown in FIGS. 1, 2, and 3, oxide region 116 of MOSFET 100 may be partially disposed over and formed within at least a portion N-type region 112, P-well 106, and epitaxial layer 104. Oxide region 116 may also be partially disposed directly over, positioned on, contact, and/or partially cover (exposed portions of) N-source 112, and epitaxial layer 104, respectively. Oxide region 116 may insulate various portions, components, and/or devices of MOSFET 100, and as a result may be formed from any suitable material or material composition that includes insulative properties/characteristics. For example, oxide region 116 may be formed as a bulk silicon insulator or can be composed of an oxide substance. Additionally, materials appropriate for the composition of oxide region 116 may include, for example, silicon dioxide (SiO2), silicon nitride (SiN), hafnium oxide (HfO2), alumina (Al2O3), yttrium oxide (Y2O3), tantalum oxide (Ta2O5), titanium dioxide (TiO2), praseodymium oxide (Pr2O3), zirconium oxide (ZrO2), erbium oxide (ErOx), (Al2O3), (Si3N4), (2D h-BN), ionic liquids, electric double layers, and other currently known or later developed materials having similar properties.

MOSFET 100 shown in FIGS. 1, 2, and 3 may also include a gate layer (or gate) 118. Gate layer 118 may be disposed within oxide region 116. More specifically, gate layer 118 may be disposed within, formed within, positioned within, and/or directly contact oxide region 116 of MOSFET 100. Gate layer 118 may be formed from any suitable material having conductive properties/characteristics. For example, gate layer 118 may be formed from materials including, but not limited to, N-type/P-type polysilicons, copper (Cu), aluminum (Al), platinum (Pt), tungsten (W), and other metals or metal-based materials.

Turning to FIGS. 2 and 3, epitaxial layer of MOSFET 100 may also include bottom P-well 114. Bottom P-well 114 may be disposed within epitaxial layer 104. More specifically, bottom P-well 114 may be formed directly and disposed within epitaxial layer 104. In the non-limiting example, and as shown in FIGS. 2 and 3, bottom P-well 114 may be formed and positioned within the epitaxial layer 104 beneath oxide region 116 and gate layer 118. More specifically, bottom P-well may be positioned such that the bottom corners of oxide region 116 and gate 118 are disposed completely within bottom P-well 114. Bottom P-well 114 of MOSFET 100 may be substantially conductive and may carry, receive, and/or flow an electrical current to distinct portions, components, and/or devices of MOSFET 100, as discussed herein. Bottom P-well 114 may be formed from any suitable material or composition of material that may include substantially conductive properties/characteristics. For example, and as discussed herein, bottom P-well 114 may be formed by doping materials formed within MOSFET 100 (e.g., epitaxial layer 104) via channeling implantation. Additionally, bottom P-well 114 reduces the electric field at the edges of oxide region 116.

In the non-limiting example shown in FIG. 2 and FIG. 3, bottom P-well 114 may include at least one distinct area. More specifically, and with reference to FIGS. 2 and 3, bottom P-well may include four distinct portions. More specifically, and with reference to FIGS. 2 and 3 and FIGS. 17-20 and FIG. 28, bottom P-well 114 of MOSFET 100 may include a first area 124, a second area 126, a third area 128, and a fourth area 130. First area 124 may be disposed directly over epitaxial layer 104. More specifically, first area 124 of bottom P-well 114 may be formed within, disposed within, and/or positioned within a portion or section of epitaxial layer 104. The section of epitaxial layer 104 may be positioned between and/or may separate first area 124 of bottom P-well 114 and substrate 102. First area 124 of bottom P-well 114 may include a first doping concentration (DC1). That is, and as discussed herein, first portion 124 of bottom P-well 114 may be formed by performing a doping process or technique, for example channeling implantation, on a portion of epitaxial layer 104. First portion 124 may be formed by doping epitaxial layer 104 with a first or predetermined ion concentration under first or predetermined operational parameters. The ion concentration and/or operational parameters may determine characteristics of first portion 124. For example, and as shown in FIG. 1, first portion 124 of deep P-well 108 may extend into epitaxial layer 104 a predetermined depth (D).

Second area 126 of bottom P-well 114 may be disposed directly over first area 124. More specifically, second area 126 of bottom P-well 114 may be formed, disposed, and/or positioned directly over first area 124. Similar to first aera 124, second area 126 of bottom P-well 114 may include a second doping concentration (DC2). Second doping concentration (DC2) may be distinct from first doping concentration (DC1) of first area 124. For example, the first doping concentration (DC1) of first area 124 may be less than the second doping concentration (DC2) of second area 126. As discussed herein, second area 126 of bottom P-well 114 may be formed by performing a doping process or technique, for example channeling implantation, on a portion of epitaxial layer 104. Second area 126 may be formed by doping a portion of epitaxial layer 104 formed above first area 124 with a second or predetermined ion concentration under second or predetermined operational parameters. The ion concentration and/or operational parameters may determine characteristics of second area 126.

Third area 128 of bottom P-well 114 may be disposed directly over second area 126. More specifically, third area 128 of bottom P-well 114 may be formed, disposed, and/or positioned directly over second area 126. Similar to second area 126, third area 128 of bottom P-well 114 may include a third doping concentration (DC3). Third doping concentration (DC3) may be distinct from second doping concentration (DC2) of second area 126. For example, the second doping concentration (DC2) of second area 126 may be less than the third doping concentration (DC3) of third area 128. As discussed herein, third area 128 of bottom P-well 114 may be formed by performing a doping process or technique, for example channeling implantation, on a portion of epitaxial layer 104. Third area 128 may be formed by doping a portion of epitaxial layer 104 formed above second area 126 with a third or predetermined ion concentration under third or predetermined operational parameters. The ion concentration and/or operational parameters may determine characteristics of third area 128.

Fourth area 130 of bottom P-well 114 may be disposed directly over third area 128. More specifically, fourth area 130 of bottom P-well 114 may be formed, disposed, and/or positioned directly over third area 128. Similar to third area 128, fourth area 130 of bottom P-well 114 may include a fourth doping concentration (DC4). Fourth doping concentration (DC4) may be distinct from third doping concentration (DC3) of third area 128. For example, the fourth doping concentration (DC4) of fourth area 130 may be less than the third doping concentration (DC3) of third area 128. As discussed herein, fourth area 130 of bottom P-well 114 may be formed by performing a doping process or technique, for example channeling implantation, on a portion of epitaxial layer 104. Fourth area 130 may be formed by doping a portion of epitaxial layer 104 formed above third area 128 with a fourth or predetermined ion concentration under third or predetermined operational parameters. The ion concentration and/or operational parameters may determine characteristics of fourth area 130.

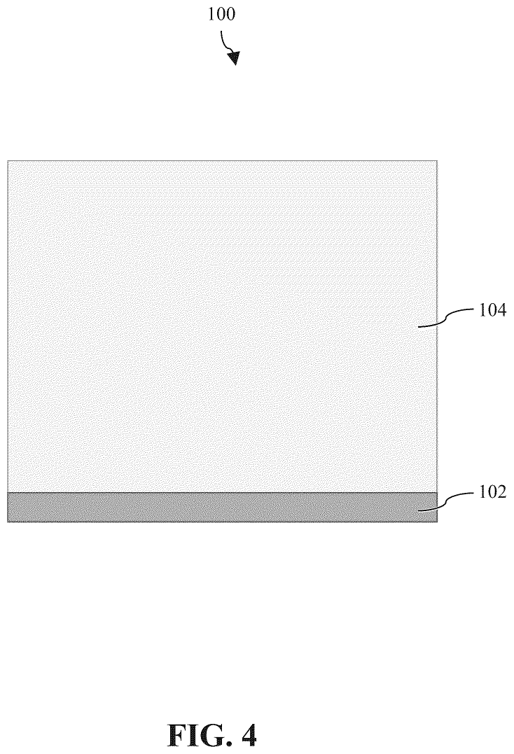

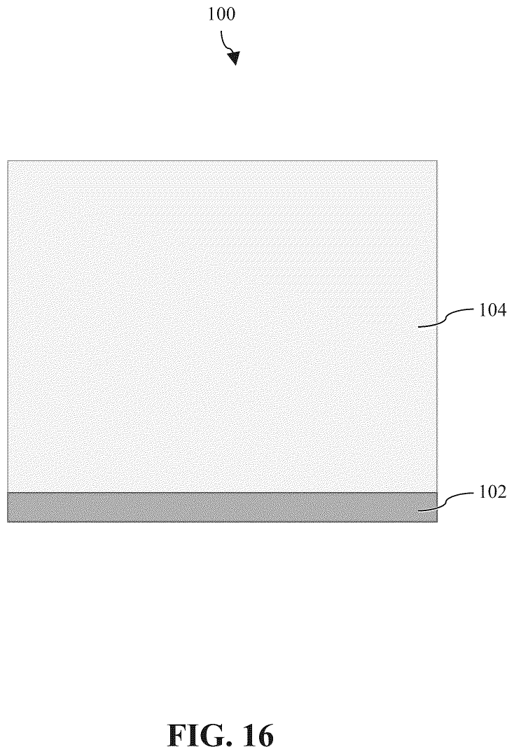

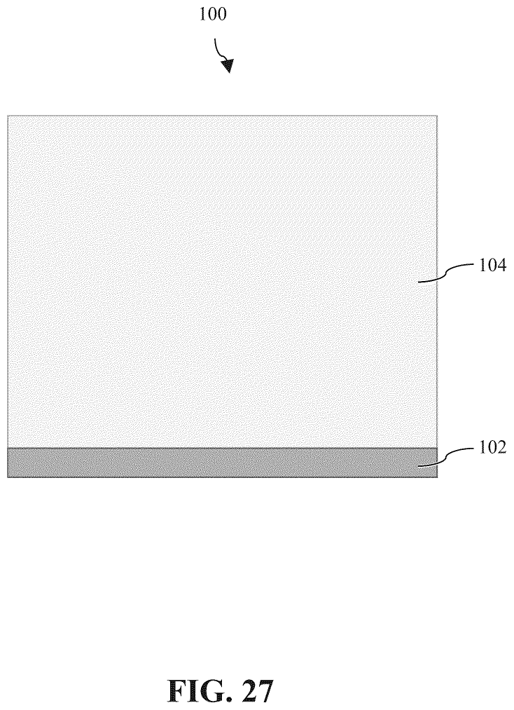

FIGS. 4-35 show various cross-sectional front views of MOSFET 100 undergoing a build process. More specifically, FIGS. 4-15 depict the building, formation, and/or manufacturing of MOSFET 100 shown in FIG. 1. FIGS. 16-26 depict the building, formation, and/or manufacturing of MOSFET 100 shown in FIG. 2. FIGS. 27-35 depict the building, formation, and/or manufacturing of MOSFET 100 shown in FIG. 3. Each of the features, components, devices, portion, and/or layers of MOSFET 100 may be formed or manufactured therein using any suitable manufacturing methods, processes, or techniques. That is, features, components, devices, portions, and/or layers of MOSFET 100 may be formed using any suitable material deposition, material removal, and/or layer formation techniques or processes, as discussed herein. Some suitable processes or techniques may include, but are not limited to, material growing/growth, material deposition, chemical-mechanical polishing (CMP), doping/ion implantation, bonding, annealing, etching, masking, photolithography, metal organic chemical vapor deposition (MOCVD), electron beam (E-beam) evaporation, and so on. Additionally, it is understood that similarly numbered and/or named components may function in a substantially similar fashion. Redundant explanation of these components has been omitted for clarity.

FIG. 4 shows the formation of epitaxial layer 104 over substrate 102. Specifically, a material forming epitaxial layer 104 may be epitaxially-grown over and may substantially cover substrate 102.

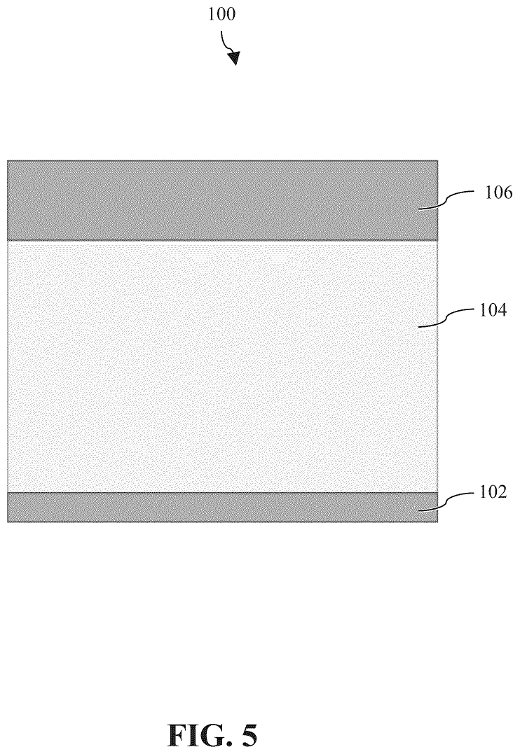

FIG. 5 depicts the formation of P-well 106. A portion of epitaxial layer 104 may be doped using channeling implantation processes to form P-well 106. Channeling implantations is also preferably used to form deep P-wells 108 and/or bottom P-well 114. Epitaxial layer 104 may be doped using ion implantation at a calibrated or predetermined angle. Doping of epitaxial layer 104 using channeling implantation to form bottom P-well 106 may be performed using specified operational parameters, including channeling implantation n of ions with a specified ion concentration, doping the portion of epitaxial layer 104 to form the bottom P-well 106 a predetermined distance, and performing channeling implantation on epitaxial layer 104 at a predetermined temperature. In one embodiment, the implant sequence is: 1) JFET (channeling implant); 2) Deep P (channeling implant); 3) P-well (random implant); 4) N+ source (random implant); and 5) P+ source (random implant).

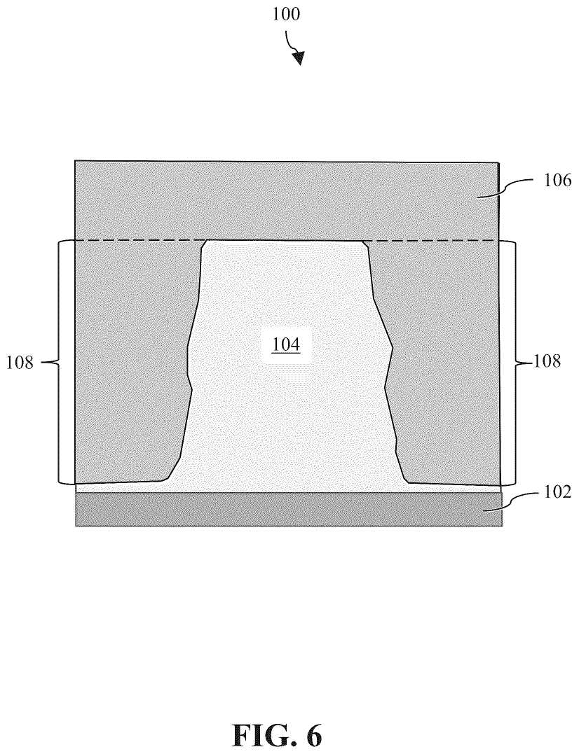

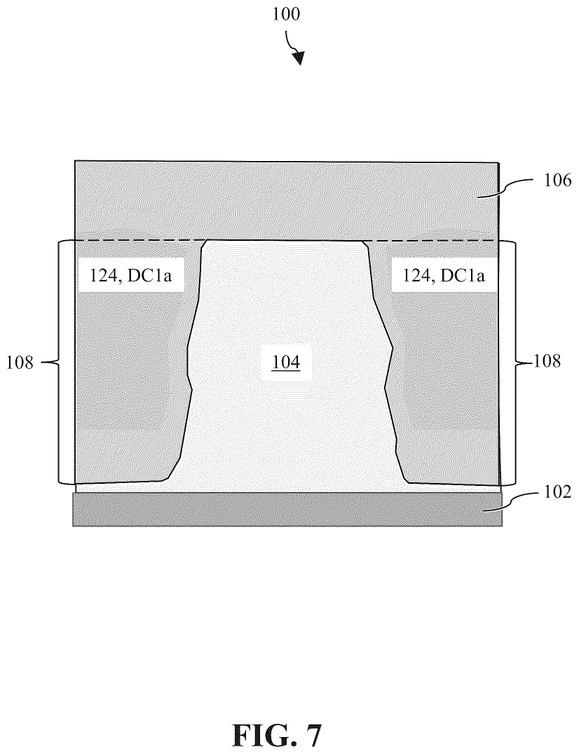

FIG. 6-10 depicts the formation of the at least one deep P-well 108. In a non-limiting example, a portion of epitaxial layer 104 may be doped via channeling implantation to form distinct portions of P-well 106. In a non-limiting example, first deep P-well and second deep P-well are formed within the epitaxial layer, where first deep P-well is positioned opposite the second deep P-well, and vice versa. In the non-limiting example, a portion of epitaxial layer 104 may be doped using deep or channeling implantation processes to form deep P-well 108. More specifically, epitaxial layer 104 may be doped using channeling implantation (e.g., ion implantation at a calibrated or predetermined angle) to form first area 124 of deep P-well 108. Doping the area of epitaxial layer 104 to form first area 124 of deep P-well 108 may include penetrating epitaxial layer 104 a predetermined distance (D) with first ion concentration 124 under first operational parameters to form first area 124. Operational parameters for first ion concentration 124 while performing channeling implantation may include directing ions toward epitaxial layer 104 at a predetermined angle and/or performing channeling implantation on epitaxial layer (or drift layer) 104 at a predetermined temperature. The predetermined angle may be relative to a predefined axis of the crystalline lattice (for example, the Miller Index 0001 axis or plane) for the material forming drift layer 104. In the non-limiting example shown in FIG. 7, first ion concentration DC1 may be directed toward epitaxial layer 104 at an angle substantially greater than zero) (0°) (for example an angle in the range of 1 to 15 degrees) and/or relatively parallel to the axis of epitaxial layer 104 in a channeling implantation process. Additionally in the non-limiting example, first ion concentration 124 may be directed toward epitaxial layer 104 during the channeling implantation while epitaxial layer 104 and/or the ambient temperature surrounding epitaxial layer 104 is substantially equal to a room temperature (e.g., 20° C.). That is, epitaxial layer 104 may not be substantially heated or cooled, prior to/while performing channeling implantation.

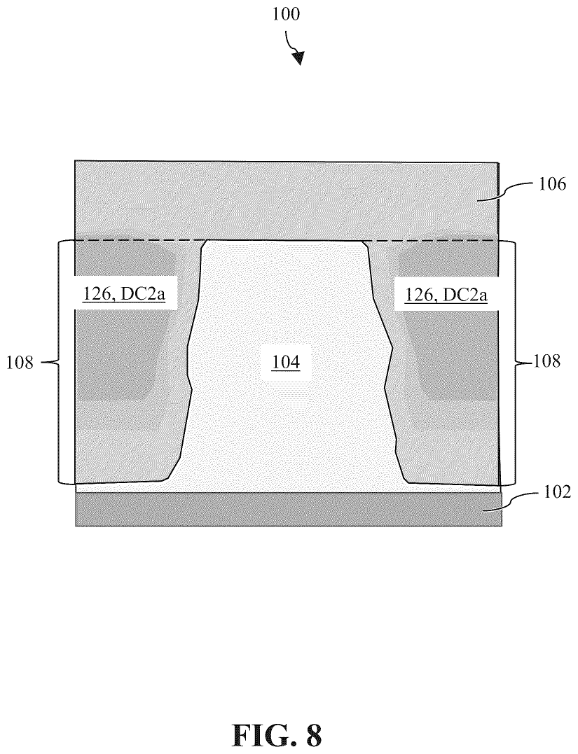

FIG. 8 also depicts the formation of deep P-well 108. In the non-limiting example, a portion of epitaxial layer 104 may be doped via channeling implantation to form distinct portions of deep P-well 108. More specifically, a portion of first area 124 of deep P-well 108 (previously epitaxial layer 104) may be doped (again) to form second area 126 of deep P-well 108. Doping the portion of epitaxial layer 104/deep P-well 108 to form second area 126 of deep P-well 108 may include penetrating deep P-well 108/layer 104 with second ion concentration DC2 under second operational parameters to form second portion (or second area) 126. The second ion concentration DC2 may be directed toward epitaxial layer 104 at an angle substantially greater than zero) (0°) (for example an angle in the range of 1 to 15 degrees) and/or relatively parallel to the axis of epitaxial layer 104 in a channeling implantation process.

The second ion concentration DC2 and second operational parameters may be distinct from the first ion concentration DC1 and first operational parameters used to form first portion 124 of deep P-well 108. For example, second ion concentration DC2 may be directed toward epitaxial layer 104 during the random ion implantation while epitaxial layer 104 and/or the ambient temperature surrounding drift (or epitaxial) layer 104 is greater than a room temperature (e.g., approximately 500° C.). That is, drift (or epitaxial) layer 104 may be substantially heated, prior to/while performing the random ion implantation process, as discussed herein.

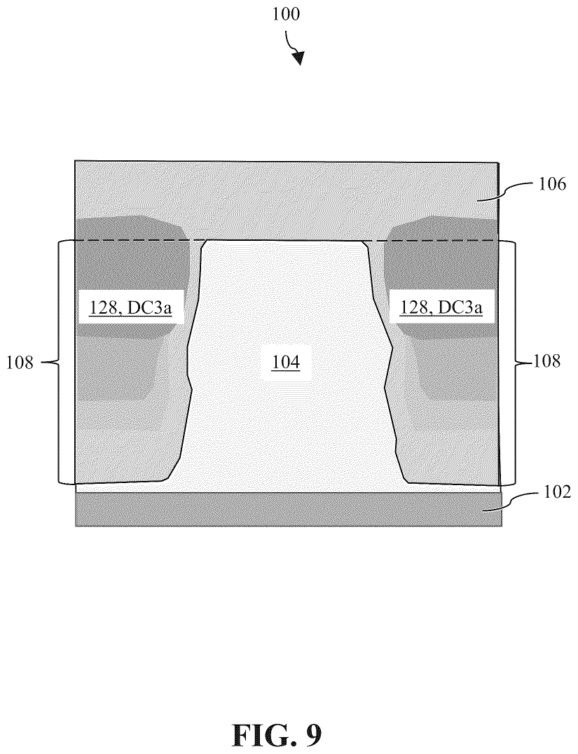

FIG. 9 also depicts the formation of deep P-well 108. In the non-limiting example, a portion of epitaxial layer 104 may be doped via channeling implantation to form distinct portions of deep P-well 108. More specifically, a portion of second area 126 of deep P-well 108 (previously epitaxial layer 104) may be doped (again) to form third area 128 of bottom P-well 114. Doping the portion of epitaxial layer 104/deep P-well 108 to form third area 128 of deep P-well 108 may include penetrating deep P-well 108/layer 104 with third ion concentration DC3 under third operational parameters to form third area 128. The third ion concentration DC3 may be directed toward epitaxial layer 104 at an angle substantially greater than zero) (0°) (for example an angle in the range of 1 to 15 degrees) and/or relatively parallel to the axis of epitaxial layer 104 in a channeling implantation process. The third ion concentration DC3 and third operational parameters may be distinct from the second ion concentration and second operational parameters used to form second portion 126 of deep P-well 108. For example, second ion concentration 126 may be directed toward epitaxial layer 104 during the random ion implantation while epitaxial layer 104 and/or the ambient temperature surrounding drift layer 104 is greater than a room temperature (e.g., approximately 500° C.). That is, drift layer 104 may be substantially heated, prior to/while performing the random ion implantation process, as discussed herein.

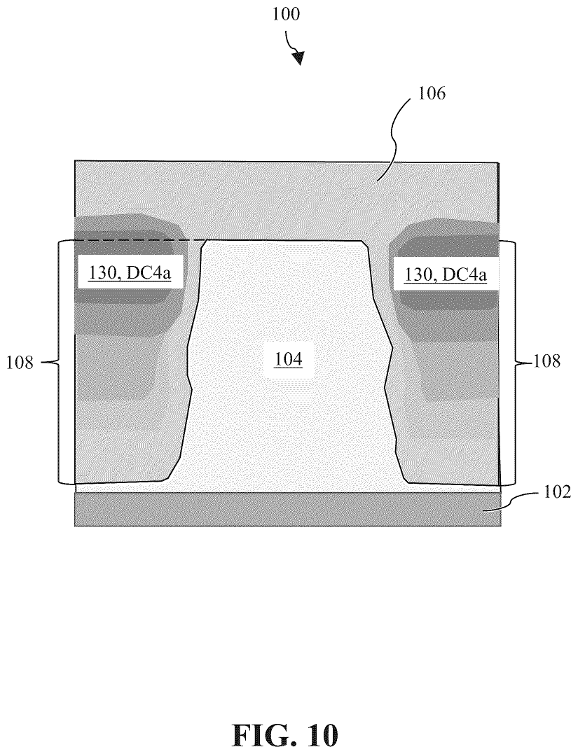

FIG. 10 also depicts the formation of deep P-well 108. In the non-limiting example, a portion of epitaxial layer 104 may be doped via channeling implantation to form distinct portions of deep P-well 108. More specifically, a portion of third area 128 of deep P-well 108 (previously epitaxial layer 104) may be doped (again) to form fourth area 130 of bottom P-well 114. Doping the portion of epitaxial layer 104/deep P-well 108 to form fourth area 130 of deep P-well 108 may include penetrating deep P-well 108/layer 104 with fourth ion concentration DC4 under fourth operational parameters to form fourth area 130. The fourth ion concentration DC4 may be directed toward epitaxial layer 104 at an angle substantially greater than zero) (0°) (for example an angle in the range of 1 to 15 degrees) and/or relatively parallel to the axis of epitaxial layer 104 in a channeling implantation process. The fourth ion concentration DC4 and fourth operational parameters may be distinct from the third ion concentration and third operational parameters used to form third area 128 of deep P-well 108. For example, second ion concentration 126 may be directed toward epitaxial layer 104 during the random ion implantation while epitaxial layer 104 and/or the ambient temperature surrounding drift layer 104 is greater than a room temperature (e.g., approximately 500° C.). That is, drift layer 104 may be substantially heated, prior to/while performing the random ion implantation process, as discussed herein.

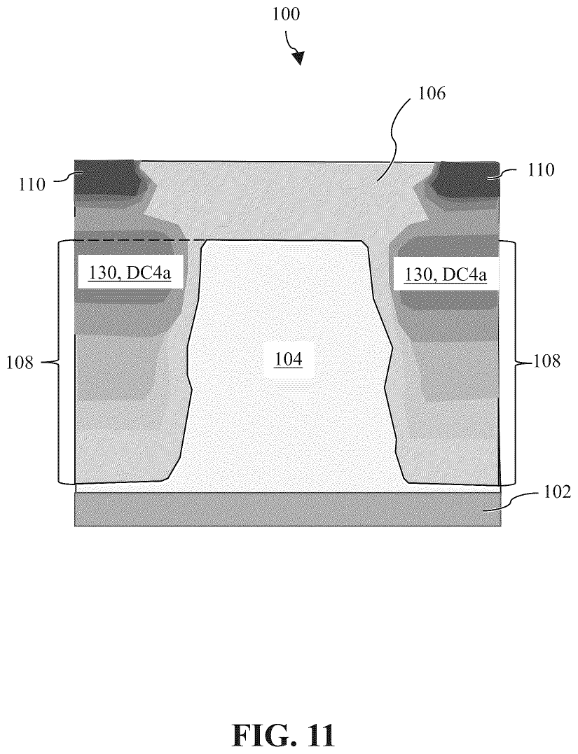

FIG. 11 depicts the formation of P-type region 110 within MOSFET 100. More specifically, a portion of P-well 106 may be doped to form P-type region 110 within P-well 106.

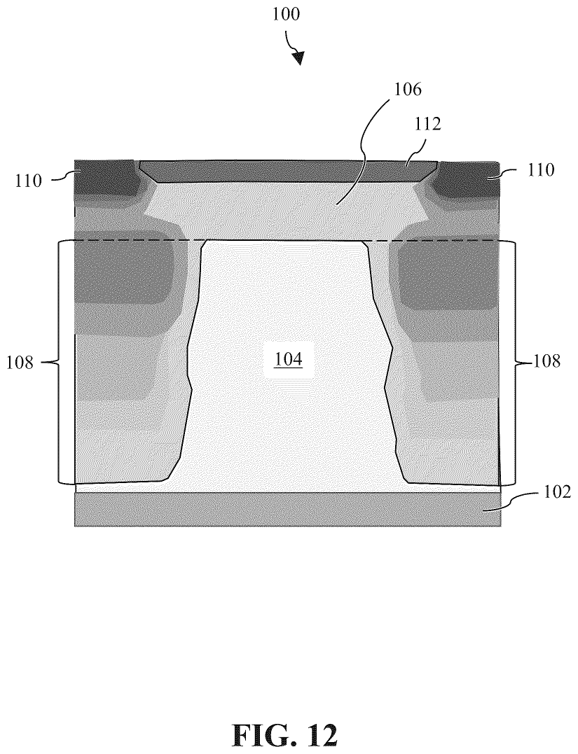

FIG. 12 depicts the formation of N-source (or N-type region) 112 within MOSFET 100. More specifically, a portion of P-well 106 may be doped to form N-source 112 within P-well 106.

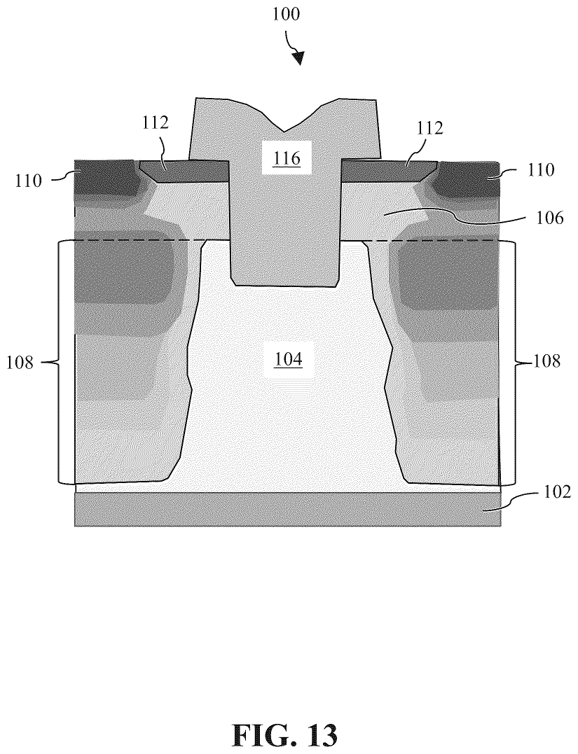

FIG. 13 depicts the formation of oxide region 116. In a non-limiting example, a trench is etched using a known trench etching process. In this embodiment, etching is performed using a mask with an opening disposed above the surface of MOSFET 100 such that the mask has an opening where trench 132 is to be located, and etching of MOSFET 100 occurs through the mask opening. An oxide region 116 may be formed within the etched trench over various portions, components, and/or devices of MOSFET 100. More specifically, and as shown in FIGS. 1 and 2, oxide region 116 of MOSFET 100 may be disposed directly over, positioned on, contact, and/or partially cover (exposed portions of) N-source 112. Oxide region 116 may insulate various portions, components, and/or devices of MOSFET 100, and as a result may be formed from any suitable material or material composition that includes insulative properties/characteristics. For example, oxide region 116 may be formed as a bulk silicon insulator or can be composed of an oxide substance. Additionally, materials appropriate for the composition of oxide region 116 may include, for example, silicon dioxide (SiO2), silicon nitride (SiN), hafnium oxide (HfO2), alumina (Al2O3), yttrium oxide (Y2O3), tantalum oxide (Ta2O5), titanium dioxide (TiO2), praseodymium oxide (Pr2O3), zirconium oxide (ZrO2), erbium oxide (ErOx), (Al2O3), (Si3N4), (2D h-BN), ionic liquids, electric double layers, and other currently known or later developed materials having similar properties.

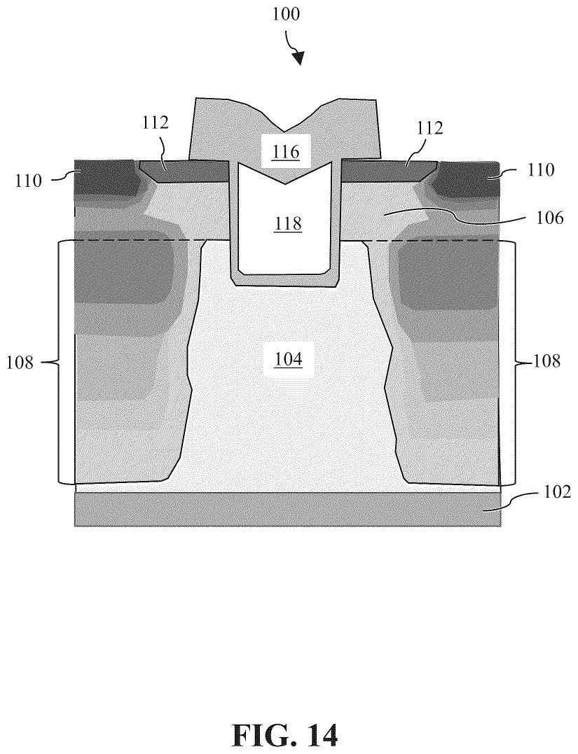

FIG. 14 depicts the formation of gate layer 118. MOSFET 100 shown in FIGS. 1, 2, and 3 may also include a gate layer 118. Gate layer 118 may be disposed within oxide region 116. More specifically, gate layer 118 may be disposed within, formed within, positioned within, and/or directly contact oxide region 116 of MOSFET 100. Gate layer 118 may be formed from any suitable material having conductive properties/characteristics. For example, gate layer 118 may be formed from materials including, but not limited to, N-type/P-type polysilicons, copper (Cu), aluminum (Al), platinum (Pt), tungsten (W), and other metals or metal-based materials.

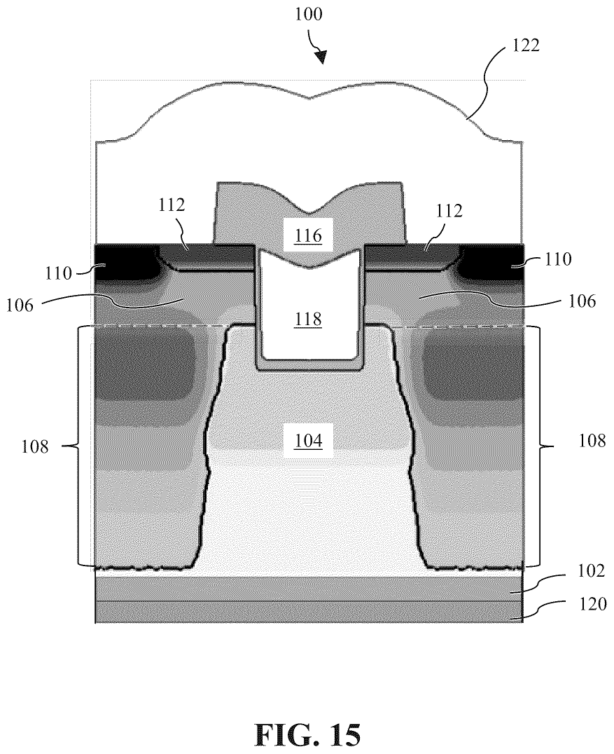

FIG. 15 also depicts the formation of the drain contact 120 disposed beneath the substrate 102 and a source region 122 disposed over the oxide region 116. More specifically, drain metal contact 120 is deposited beneath substrate 102. Also more specifically, the source region (or source layer) is disposed over the entire MOSFET 100 and may be composed of Ti, TiN, TiW, Aluminum or the like.

As discussed herein, FIGS. 16-26 depict the building, formation, and/or manufacturing of MOSFET 100 shown in FIG. 2.

FIG. 16 shows the formation of epitaxial layer 104 over substrate 102. Specifically, a material forming epitaxial layer 104 may be epitaxially-grown over and may substantially cover substrate 102.

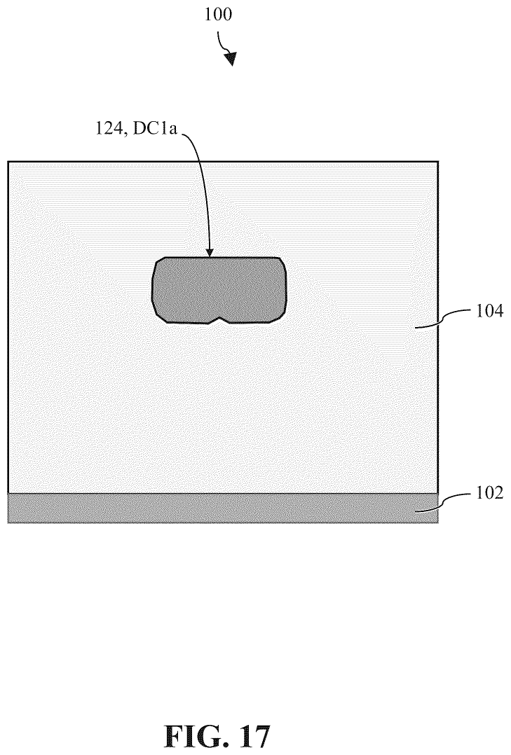

FIG. 17-20 depicts the formation of bottom P-well 114. In a non-limiting example, a portion of epitaxial layer 104 may be doped via channeling implantation to form distinct portions of bottom P-well 114. In the non-limiting example, a portion of epitaxial layer 104 may be doped using deep or channeling implantation processes to form bottom P-well 114. More specifically, epitaxial layer 104 may be doped using channeling implantation (e.g., ion implantation at a calibrated or predetermined angle) to form first area 124 of bottom P-well 114. Doping the area of epitaxial layer 104 to form first area 124 of bottom P-well 114 may include penetrating epitaxial layer 104 a predetermined distance (D) with first ion concentration DC1 under first operational parameters to form first area 124. Operational parameters for first ion concentration 124 while performing channeling implantation may include directing ions toward epitaxial layer 104 at a predetermined angle and/or performing channeling implantation on drift layer (or epitaxial layer) 104 at a predetermined temperature. The predetermined angle may be relative to a predefined axis of the crystalline lattice for the material forming drift layer 104. In the non-limiting example shown in FIG. 17, first ion concentration 124 may be directed toward epitaxial layer 104 at an angle substantially greater than zero) (0°) (for example, an angle in the range of 1-15 degrees) and/or relatively parallel to the axis of epitaxial layer 104. Additionally in the non-limiting example, first ion concentration 124 may be directed toward epitaxial layer 104 during the channeling implantation while epitaxial layer 104 and/or the ambient temperature surrounding epitaxial layer 104 is substantially equal to a room temperature (e.g., 20° C.). That is, epitaxial layer 104 may not be substantially heated or cooled, prior to/while performing channeling implantation.

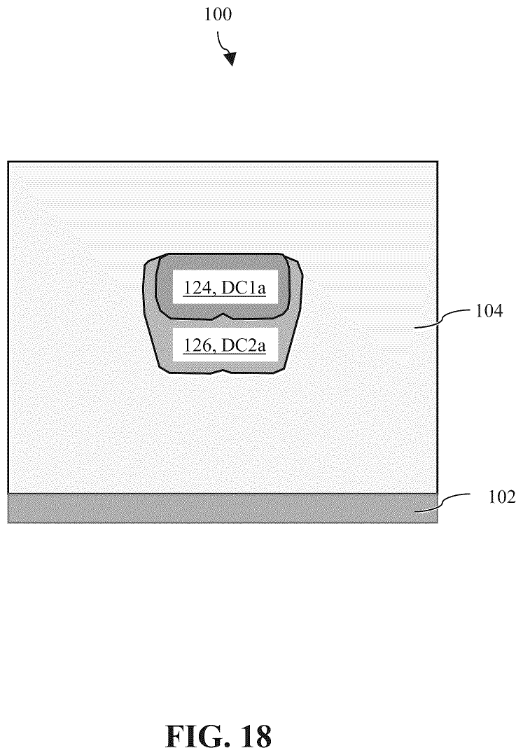

FIG. 18 also depicts the formation of bottom P-well 114. In the non-limiting example, a portion of epitaxial layer 104 may be doped via channeling implantation to form distinct portions of bottom P-well 114. More specifically, a portion of first area 124 of bottom P-well 114 (previously epitaxial layer 104) may be doped (again) to form second area 126 of bottom P-well 114. Doping the portion of epitaxial layer 104/deep P-well 108 to form second area 126 of bottom P-well 114 may include penetrating bottom P-well 114/layer 104 with second ion concentration DC2 under second operational parameters to form second portion 126. The second ion concentration DC2 and second operational parameters may be distinct from the first ion concentration and first operational parameters used to form first portion 124 of bottom P-well 114, For example, second ion concentration DC2 may be directed toward epitaxial layer 104 during the random ion implantation while epitaxial layer 104 and/or the ambient temperature surrounding drift layer 104 is greater than a room temperature (e.g., approximately 500° C.). That is, drift layer 104 may be substantially heated, prior to/while performing the random ion implantation process, as discussed herein.

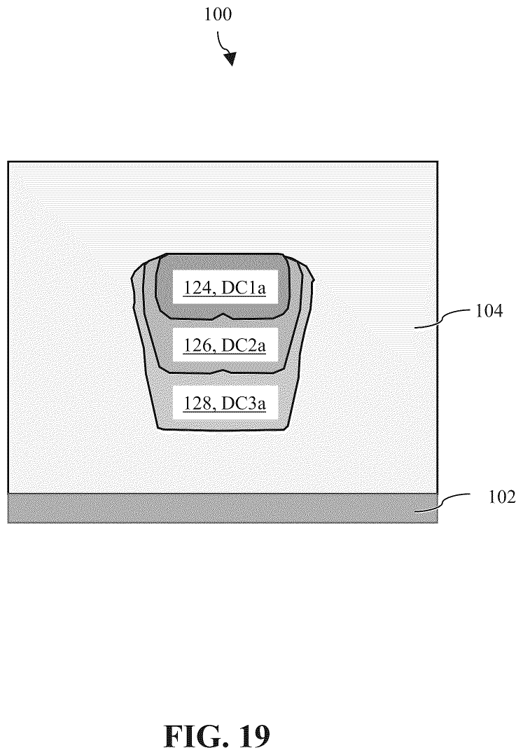

FIG. 19 also depicts the formation of bottom P-well 114. In the non-limiting example, a portion of epitaxial layer 104 may be doped via channeling implantation to form distinct portions of bottom P-well 114. More specifically, a portion of second area 126 of bottom P-well 114 (previously epitaxial layer 104) may be doped (again) to form third area 128 of bottom P-well 114. Doping the portion of epitaxial layer 104/bottom P-well 114 to form third area 128 of bottom P-well 114 may include penetrating bottom P-well 114/layer 104 with third ion concentration DC3 under third operational parameters to form third area 128. The third ion concentration DC3 and third operational parameters may be distinct from the second ion concentration and third operational parameters used to form second portion 126 of bottom P-well 114. For example, second ion concentration DC3 may be directed toward epitaxial layer 104 during the random ion implantation while epitaxial layer 104 and/or the ambient temperature surrounding drift layer 104 is greater than a room temperature (e.g., approximately 500° C.). That is, drift layer 104 may be substantially heated, prior to/while performing the random ion implantation process, as discussed herein.

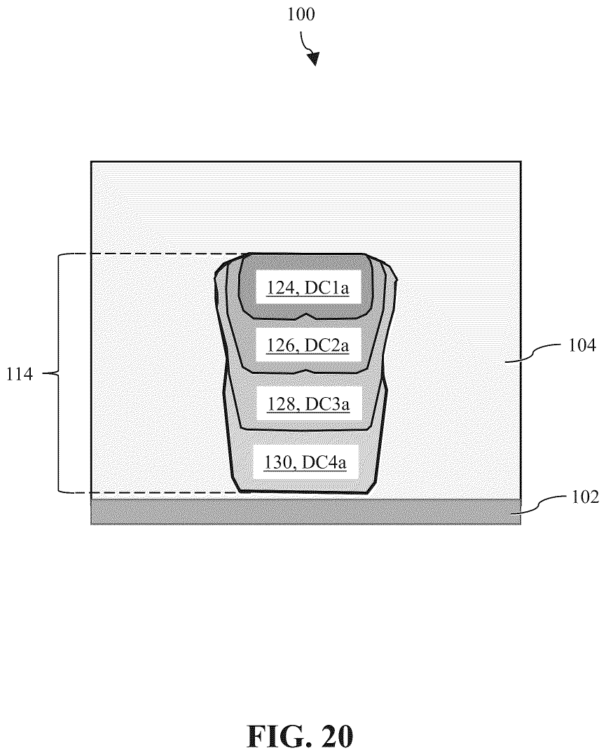

FIG. 20 also depicts the formation of bottom P-well 114. In the non-limiting example, a portion of epitaxial layer 104 may be doped via channeling implantation to form distinct portions of bottom P-well 114. More specifically, a portion of third area 128 of bottom P-well 114 (previously epitaxial layer 104) may be doped (again) to form fourth area 130 of bottom P-well 114. Doping the portion of epitaxial layer 104/bottom P-well 114to form fourth area 130 of bottom P-well 114 may include penetrating bottom P-well 114/layer 104 with fourth ion concentration DC4 under fourth operational parameters to form fourth area 130. The fourth ion concentration DC4 and fourth operational parameters may be distinct from the third ion concentration and third operational parameters used to form third area 128 of bottom P-well 114. For example, fourth ion concentration DC4 may be directed toward epitaxial layer 104 during the random ion implantation while epitaxial layer 104 and/or the ambient temperature surrounding drift layer 104 is greater than a room temperature (e.g., approximately 500° C.). That is, drift layer 104 may be substantially heated, prior to/while performing the random ion implantation process, as discussed herein.

FIGS. 17-20 depict the formation of the bottom P-well 114 as implanting the first area 124, second area 126, third area 128 and fourth area 130 successively from the shallowest first area 124 down to the deepest fourth area 130. However, the bottom P-well 114 may also be formed by implanting the first, second, third and fourth areas 124, 126, 128 and 130 in the opposite order. In other words, the deepest fourth area 130 may be implanted first, then the third area 128 may be implanted second, then the second area 126 may be implanted third and finally shallowest first area 124 may be implanted last.

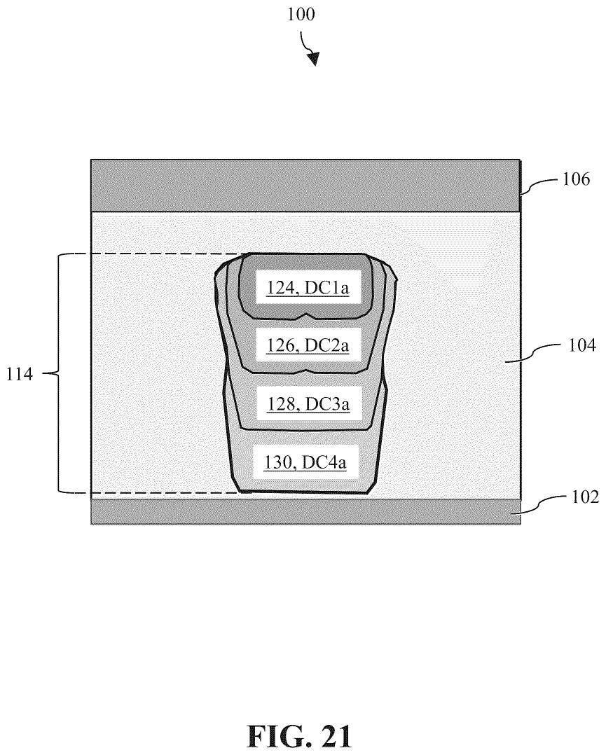

FIG. 21 depicts the formation of P-well 106. A portion of epitaxial layer 104 may be doped using channeling implantation processes to form P-well 106. Epitaxial layer 104 may be doped using ion implantation at a calibrated or predetermined angle. Doping of epitaxial layer 104 using channeling implantation to form P-well 106 may be performed using specified operational parameters, including channeling implantation n of ions with a specified ion concentration, doping the portion of epitaxial layer 104 to form the P-well 106 a predetermined distance, and performing channeling implantation on epitaxial layer 104 at a predetermined temperature.

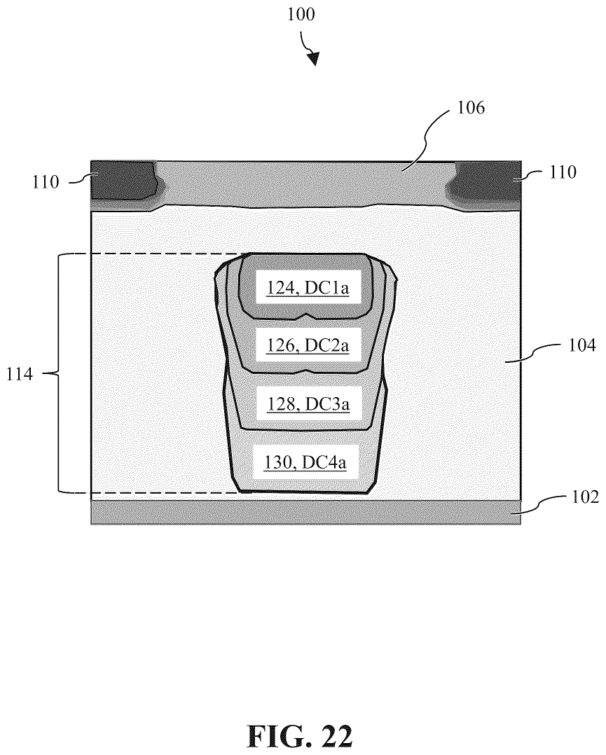

FIG. 22 depicts the formation of P-type region 110 within MOSFET 100. More specifically, a portion of P-well 106 may be doped to form P-type region 110 within P-well 106.

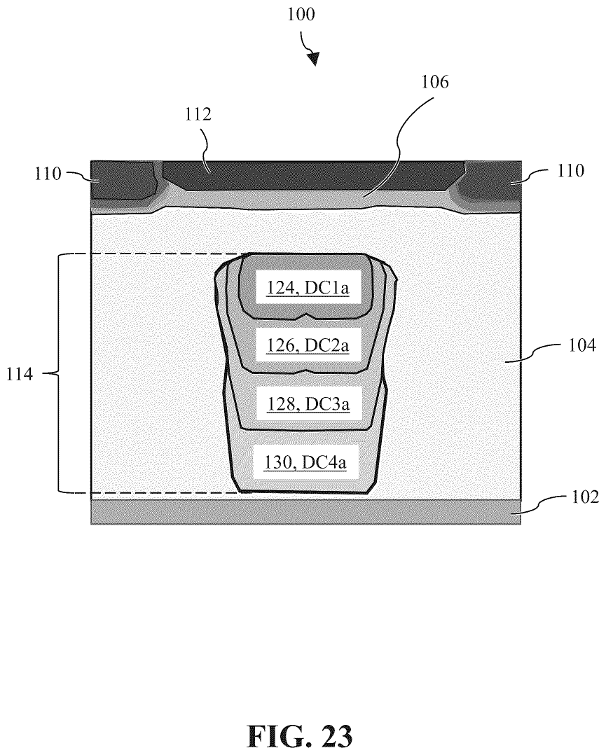

FIG. 23 depicts the formation of N-source (or N-type region) 112 within MOSFET 100. More specifically, a portion of P-well 106 may be doped to form N-source 112 within P-well 106.

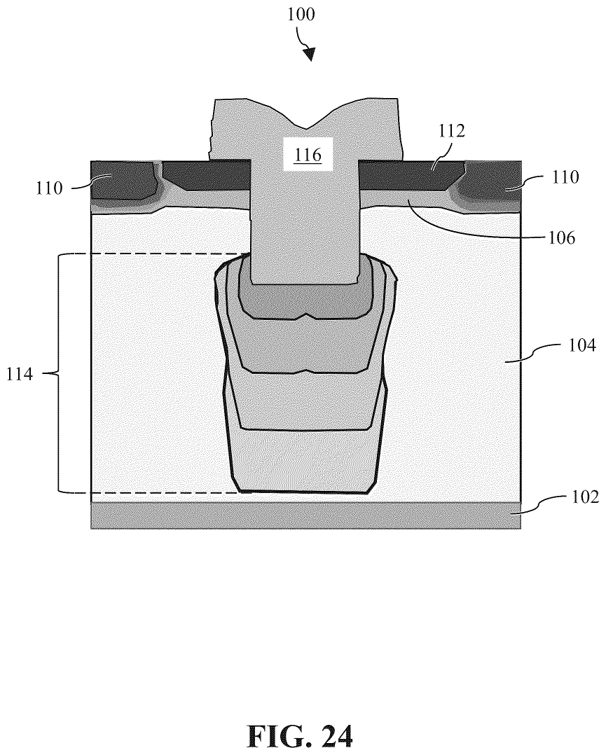

FIG. 24 depicts the formation of oxide region 116. In a non-limiting example, a trench is etched using a known trench etching process. Etching is performed using a mask with an opening disposed above the surface of MOSFET 100 such that the mask has an opening where trench 132 is to be located, and etching of MOSFET 100 occurs through the mask opening. An oxide region 116 may be formed within the etched trench over various portions, components, and/or devices of MOSFET 100. More specifically, and as shown in FIGS. 1, 2 and 3, oxide region 116 of MOSFET 100 may be disposed directly over, positioned on, contact, and/or partially cover (exposed portions of) N-source 112. Oxide region 116 may also be disposed partially within bottom P-well 114. Oxide region 116 may insulate various portions, components, and/or devices of MOSFET 100, and as a result may be formed from any suitable material or material composition that includes insulative properties/characteristics. For example, oxide region 116 may be formed as a bulk silicon insulator or can be composed of an oxide substance. Additionally, materials appropriate for the composition of oxide region 116may include, for example, silicon dioxide (SiO2), silicon nitride (SiN), hafnium oxide (HfO2), alumina (Al2O3), yttrium oxide (Y2O3), tantalum oxide (Ta2O5), titanium dioxide (TiO2), praseodymium oxide (Pr2O3), zirconium oxide (ZrO2), erbium oxide (ErOx), (Al2O3), (Si3N4), (2D h-BN), ionic liquids, electric double layers, and other currently known or later developed materials having similar properties.

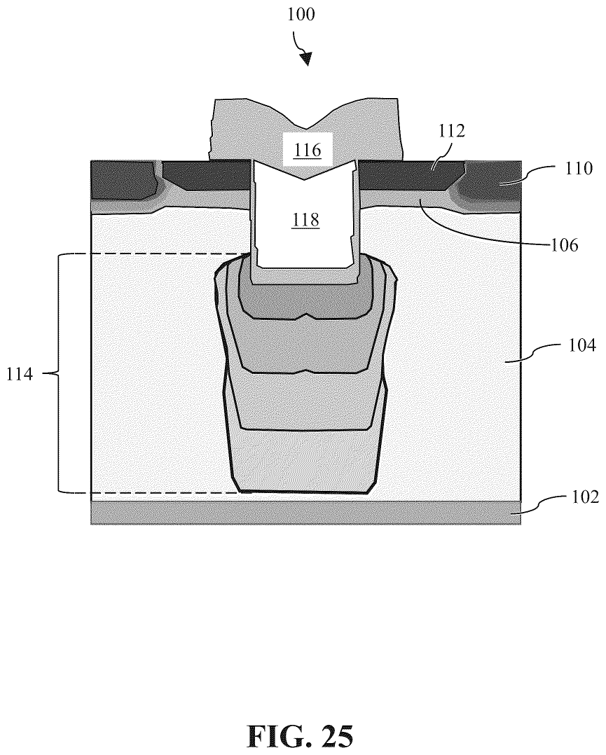

FIG. 25 depicts the formation of gate layer 118. MOSFET 100 shown in FIGS. 1, 2, and 3 may also include a gate layer 118. Gate layer 118 may be disposed within oxide region 116. More specifically, gate layer 118 may be disposed within, formed within, positioned within, and/or directly contact oxide region 116 of MOSFET 100. Gate layer (or gate layer) 118 may be formed from any suitable material having conductive properties/characteristics. For example, gate layer 118 may be formed from materials including, but not limited to, N-type/P-type polysilicons, copper (Cu), aluminum (Al), platinum (Pt), tungsten (W), and other metals or metal-based materials.

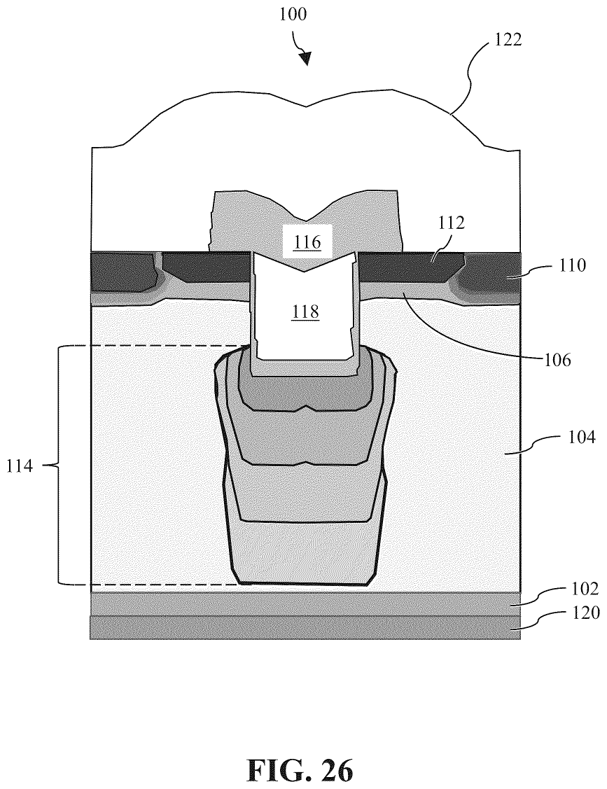

FIG. 26 also depicts the formation of the drain contact 120 disposed beneath the substrate 102 and a source region 122 disposed over the oxide region 116. More specifically, drain metal contact 120 is deposited beneath substrate 102. Also more specifically, the source region 122 (or source layer) is disposed over the entire MOSFET 100 and may be composed of Ti, TiN, TiW, Aluminum or the like.

As discussed herein, FIGS. 27-35 depict the building, formation, and/or manufacturing of MOSFET 100 shown in FIG. 3.

FIG. 27 shows the formation of epitaxial layer 104 over substrate 102. Specifically, a material forming epitaxial layer 104 may be epitaxially-grown over and may substantially cover substrate 102.

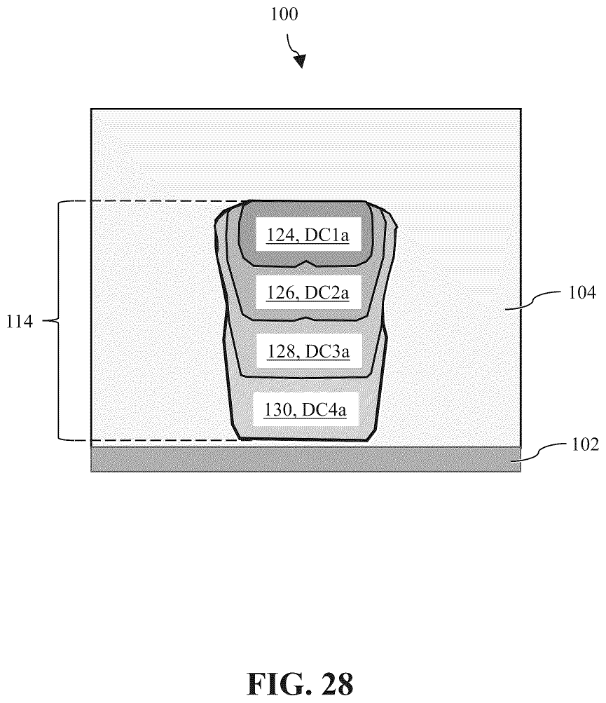

FIG. 28 depicts the formation of bottom P-well 114. The steps discussed for formation of bottom P-well 114 for MOSFET 100 shown in FIG. 3 encompass the same set of steps previously described for the formation of bottom P-well 114 for MOSFET 100 shown in FIG. 2.

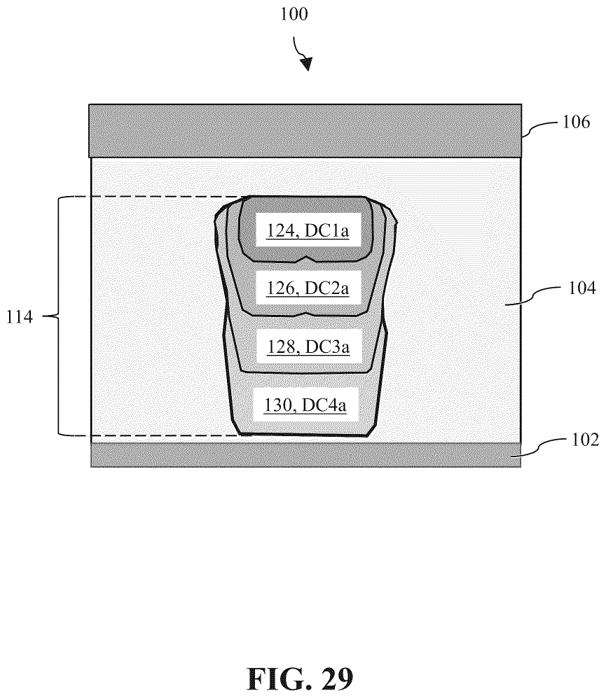

FIG. 29 depicts the formation of P-well 106. A portion of epitaxial layer 104 may be doped using channeling implantation processes to form P-well 106. Epitaxial layer 104 may be doped using ion implantation at a calibrated or predetermined angle. Doping of epitaxial layer 104 using channeling implantation to form P-well 106 may be performed using specified operational parameters, including channeling implantation n of ions with a specified ion concentration, doping the portion of epitaxial layer 104 to form the P-well 106 a predetermined distance, and performing channeling implantation on epitaxial layer 104 at a predetermined temperature. In one embodiment, the implant sequence is: 1) JFET (channeling implant); 2) Deep P (channeling implant) or BPW (channeling implant); 3) P-well (random implant); 4) N+ source (random implant); and 5) P+ source (random implant).

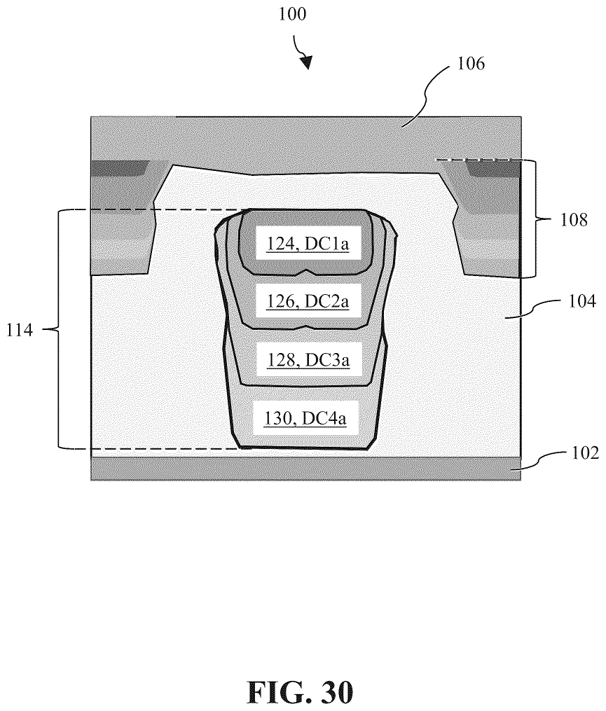

FIG. 30 depicts the formation of at least one deep P-well 108. The steps discussed for formation of deep P-well for MOSFET 100 shown in FIG. 3 encompass the same set of steps previously described for the formation of bottom P-well 114 for MOSFET 100 shown in FIG. 1.

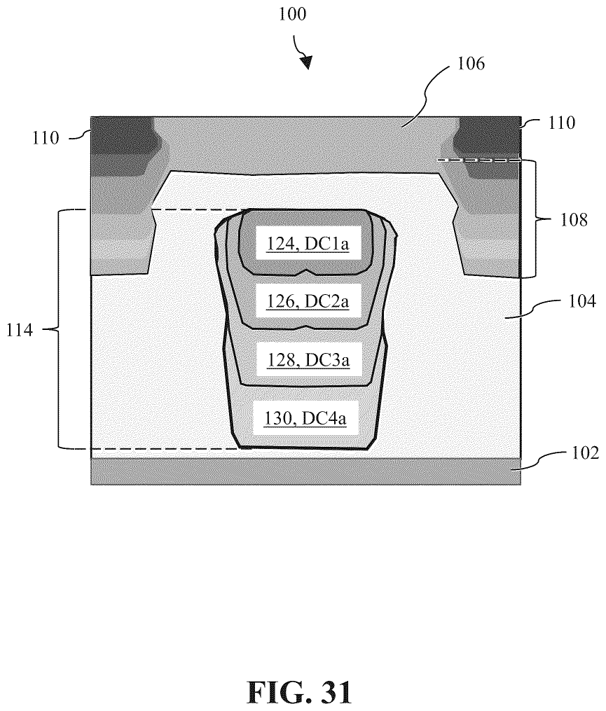

FIG. 31 depicts the formation of P-type region 110 within MOSFET 100. More specifically, a portion of P-well 106 may be doped to form P-type region 110 within P-well 106.

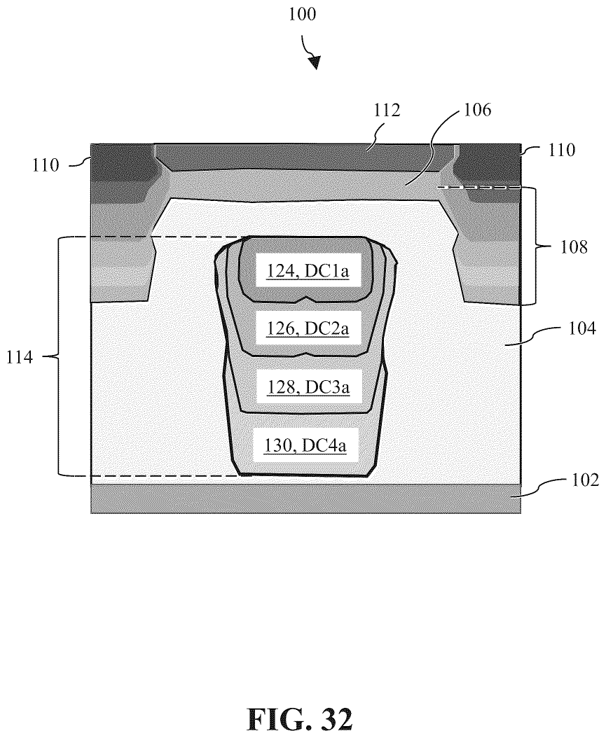

FIG. 32 depicts the formation of N-source (or N-type region) 112 within MOSFET 100. More specifically, a portion of P-well 106 may be doped to form N-source 112 within P-well 106.

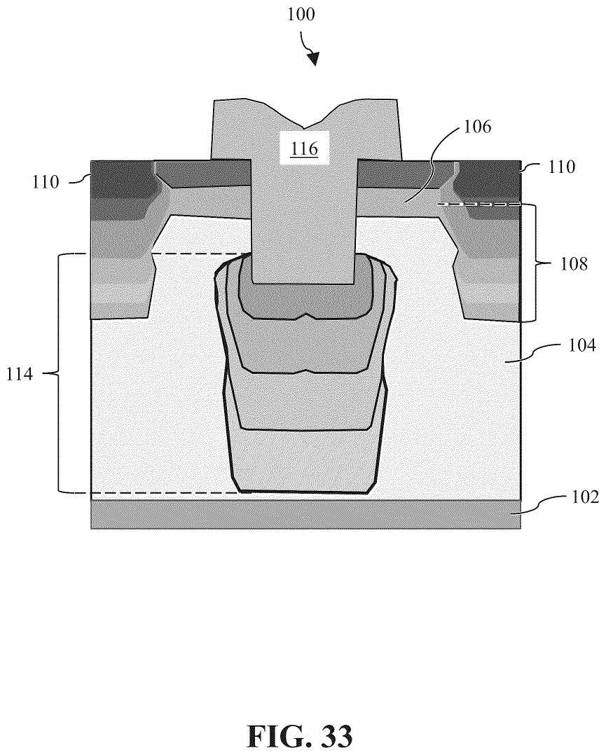

FIG. 33 depicts the formation of oxide region 116. In a non-limiting example, a trench is etched using a known trench etching process. Etching is performed using a mask with an opening disposed above the surface of MOSFET 100 such that the mask has an opening where trench 132 is to be located, and etching of MOSFET 100 occurs through the mask opening. An oxide region 116 may be formed within the etched trench over various portions, components, and/or devices of MOSFET 100. More specifically, and as shown in FIGS. 1, 2 and 3, oxide region 116 of MOSFET 100 may be disposed directly over, positioned on, contact, and/or partially cover (exposed portions of) N-source 112. Oxide region 116 may also be disposed partially within bottom P-well 114. Oxide region 116 may insulate various portions, components, and/or devices of MOSFET 100, and as a result may be formed from any suitable material or material composition that includes insulative properties/characteristics. For example, oxide region 116 may be formed as a bulk silicon insulator or can be composed of an oxide substance. Additionally, materials appropriate for the composition of oxide region 116may include, for example, silicon dioxide (SiO₂), silicon nitride (SiN), hafnium oxide (HfO2), alumina (Al2O3), yttrium oxide (Y2O3), tantalum oxide (Ta2O5), titanium dioxide (TiO2), praseodymium oxide (Pr2O3), zirconium oxide (ZrO2), erbium oxide (ErOx), (Al2O3), (Si3N4), (2D h-BN), ionic liquids, electric double layers, and other currently known or later developed materials having similar properties.

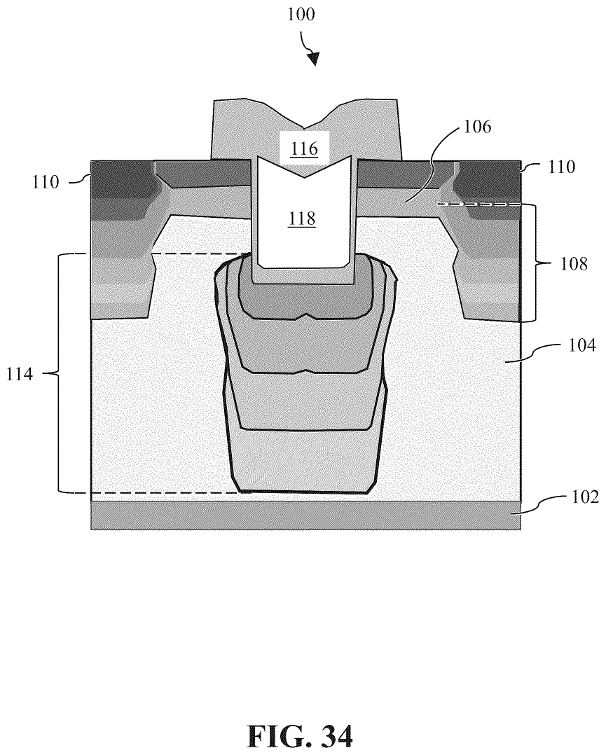

FIG. 34 depicts the formation of gate layer (or gate layer) 118. MOSFET 100 shown in FIGS. 1, 2, and 3 may also include a gate layer 118. Gate layer 118 may be disposed within oxide region 116. More specifically, gate layer 118 may be disposed within, formed within, positioned within, and/or directly contact oxide region 116 of MOSFET 100. Gate layer 118 may be formed from any suitable material having conductive properties/characteristics. For example, gate layer 118 may be formed from materials including, but not limited to, N-type/P-type polysilicons, copper (Cu), aluminum (Al), platinum (Pt), tungsten (W), and other metals or metal-based materials.

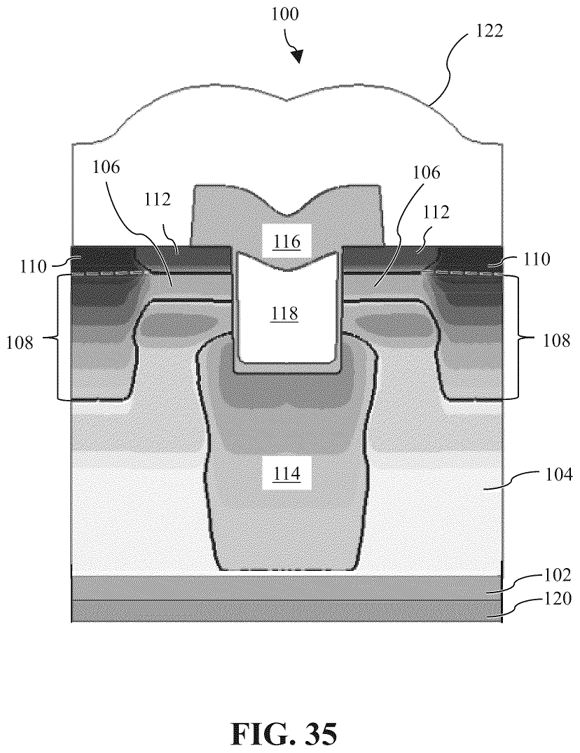

FIG. 35 also depicts the formation of the drain contact 120 disposed beneath the substrate 102 and a source region 122 disposed over the oxide region 116. More specifically, drain metal contact 120 is deposited beneath substrate 102. Also more specifically, the source region 122 (or source layer) is disposed over the entire MOSFET 100 and may be composed of Ti, TiN, TiW, Aluminum or the like.

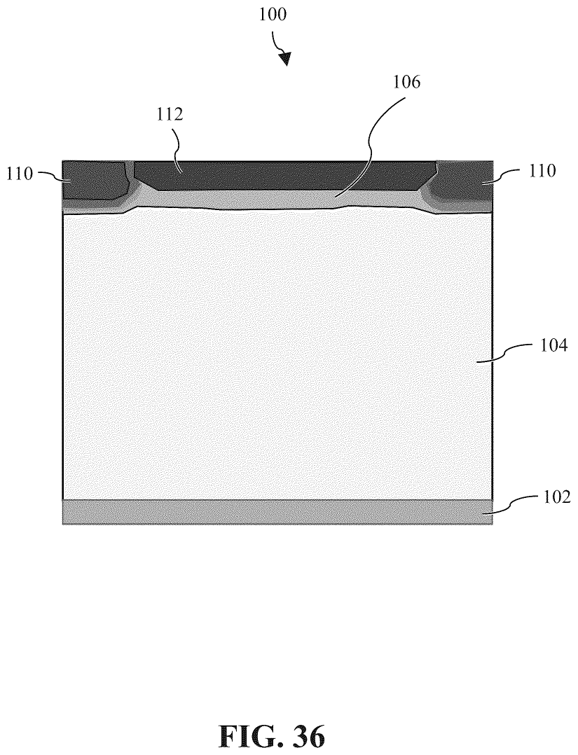

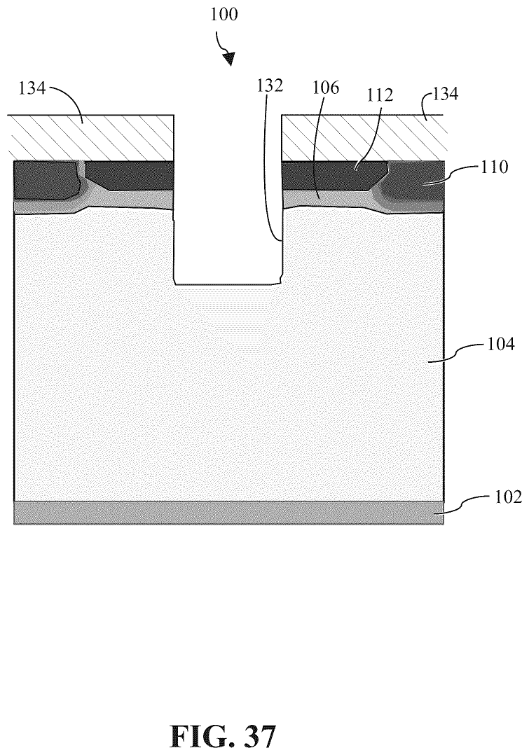

The following FIGS. 36-40 illustrate an alternative method of forming MOSFET 100 of FIGS. 1, 2 and 3, wherein the gate 118 is formed before the oxide layer 116 is formed and wherein the bottom P-well 114 is formed before the trench 132 (see FIG. 37) is formed. In previous methods described herein (e.g., as illustrated in FIGS. 13 and 14; FIGS. 24 and 25; and FIGS. 33 and 34), the oxide layer 116 is formed before gate 118 is formed. Also, in aforementioned methods described herein, (e.g., as illustrated in FIGS. 17-25; and in FIGS. 28-34), the bottom P-well is formed prior to the formation of the trench 132. Advantageously, formation of the trench 132 prior to the formation of the bottom P-well 114 enables the bottom P-well 114 to be formed with less implantation energy than the previously described methods.

Referring to FIG. 36, a cross-sectional view is depicted of the MOSFET 100 of FIG. 3 at an early stage of formation, illustrating an alternative method of forming the MOSFET 100 of FIG. 3, wherein the P-well 106, the P-type region 110, the N-source 112 and ultimately the gate 118 are formed prior to forming the bottom P-well 114. Though the alternative method of forming MOSFET 100 is illustrated with reference to FIG. 3, the alternative method may be applied to the formation of MOSFET 100 having the structure of FIGS. 1 and/or 2 as well. In FIG. 36, the P-well 106, P-type region 110 and N-source 112 have all been formed into the epitaxial layer 104, which is disposed over the substrate 102.

Referring to FIG. 37, a cross-sectional view is depicted of the MOSFET 100 of FIG. 36, illustrating the etching of a trench 132 through the N-source 112, through the P-well 106 and into the epitaxial layer 104. A hardmask 134 is disposed over the top surface of the MOSFET 100 in order to protect the unetched areas under the hardmask 134 and to guide the etching process. The hardmask 134 may be composed of an oxide or other like materials.

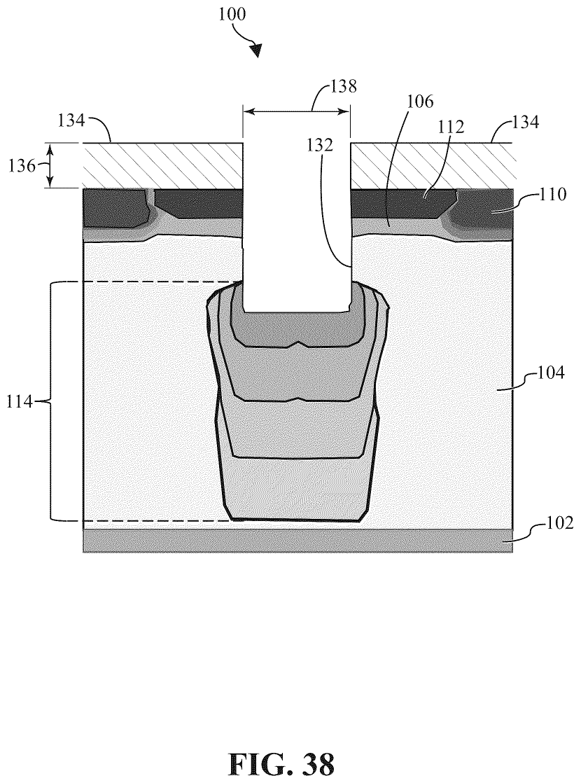

Referring to FIG. 38, a cross-sectional view is depicted of the MOSFET 100 of FIG. 37, illustrating the ion implantation of the bottom P-well 114. Advantageously, implanting the bottom P-well 114 after the trench 132 is formed and prior to the formation of the oxide layer 116 and gate 118, requires significantly less implantation energy and can form a deeper bottom P-well 114 than previously described methods.

Ion implantation of bottom P-well 114 may be performed using conventional (or random) implantation processes or using channeling implantation processes. However, channeling implantation processes require significantly less energy than random implantation processes in the formation of the bottom P-well. Additionally, as will be described herein in greater detail, the use of channeling implantation (as opposed to random implantation) to form the bottom P-well 114 and the deep P-wells 108 enables the formation of unique features of the bottom P-well 114 that are practically unobtainable through the use of random implantation processes.

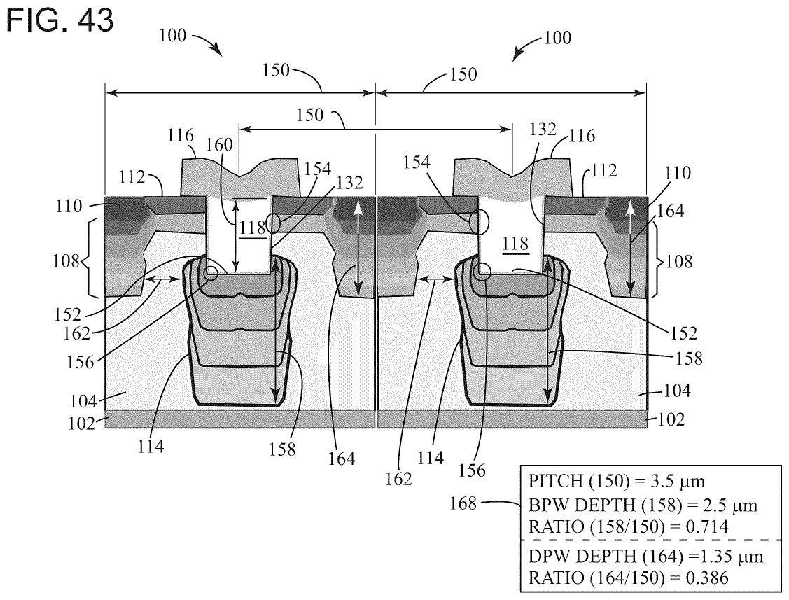

The hard mask 134 is also used to protect the underlying structures (e.g., areas of the P-well 106, P-type region 110 and N-source 112 that are covered by the hardmask 134) from damage during the implantation processes. It is important to note that the greater the implantation energy required to implant the bottom P-well 114, the greater the thickness 136 of the hardmask 134 must be in order to provide adequate protection to the underlying structures. However, the maximum aspect ratio, i.e., the ratio of the thickness 136 of the hardmask 134 to the minimum width (or critical dimension) 138 of the required opening of the hardmask 134, will not change as the thickness 136 increases. Accordingly, the minimum width 138 of the opening (which defines the minimum width of the trench 132) will disadvantageously grow as the implantation energy is increased. Moreover, the pitch (or cell pitch) 150 (see FIGS. 43-45) MOSFET 100 will also disadvantageously grow and the number of MOSFET 100 cells that can be placed in a given area will be significantly reduced.

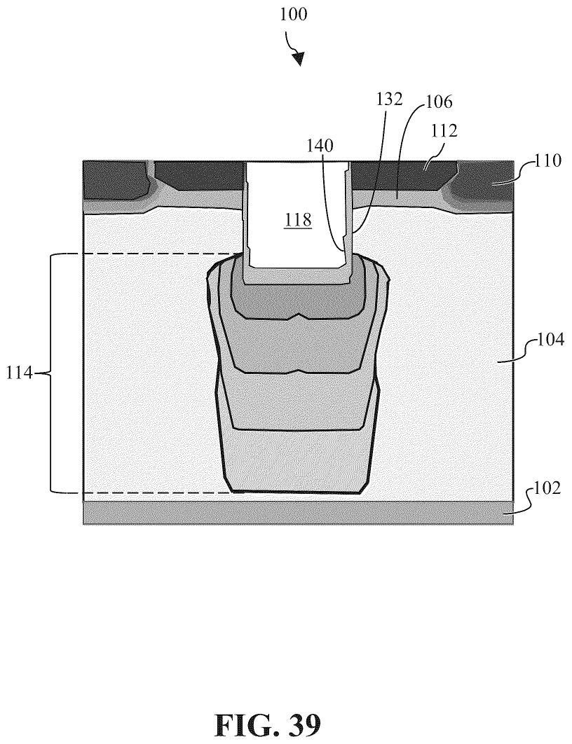

Referring to FIG. 39, a cross-sectional view is depicted of the MOSFET 100 of FIG. 38, illustrating the formation of a gate oxide layer 140 (a portion of the oxide layer 116) and the gate 118 within the trench 132. The gate oxide layer 140 is disposed on the inner surface of the trench 132. The gate oxide layer may be composed of oxide and other materials that are the same as or similar to the oxide layer 116.

Once the gate oxide layer 140 is disposed in the trench 132, the gate (or gate layer) 118 is disposed over the gate oxide layer 118 to fill the trench 132. The gate 118 may be composed of any suitable material having conductive properties/characteristics. For example, gate layer 118 may be formed from materials including, but not limited to, N-type/P-type polysilicons, copper (Cu), aluminum (Al), platinum (Pt), tungsten (W), and other metals or metal-based materials.

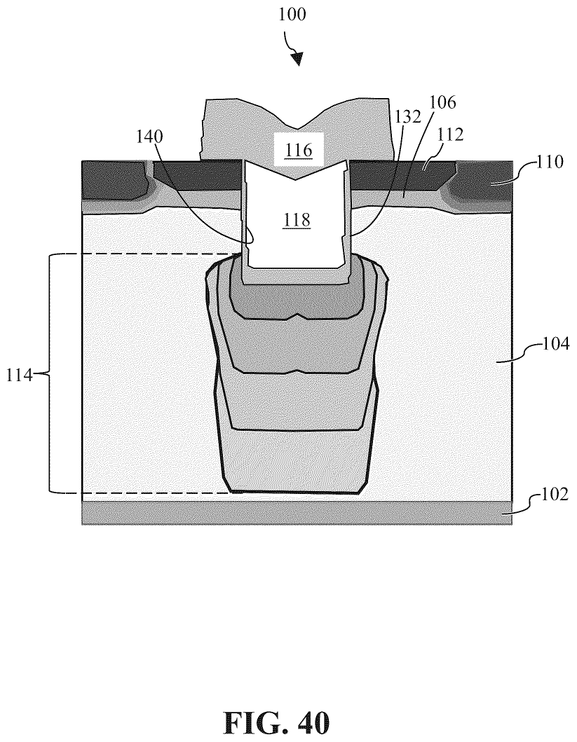

Referring to FIG. 40, a cross-sectional view is depicted of the MOSFET 100 of FIG. 39, illustrating the formation of the oxide layer 116 over the gate 118. Once the gate 118 is formed, the oxide layer 116 is formed over the MOSFET 100 to complete the structure.

Advantageously, formation of the bottom P-well 114 after the formation of the trench 132 and before the formation of the gate oxide layer 140 and gate 118 significantly reduces the amount of implantation energy required to implant the bottom P-well 114.

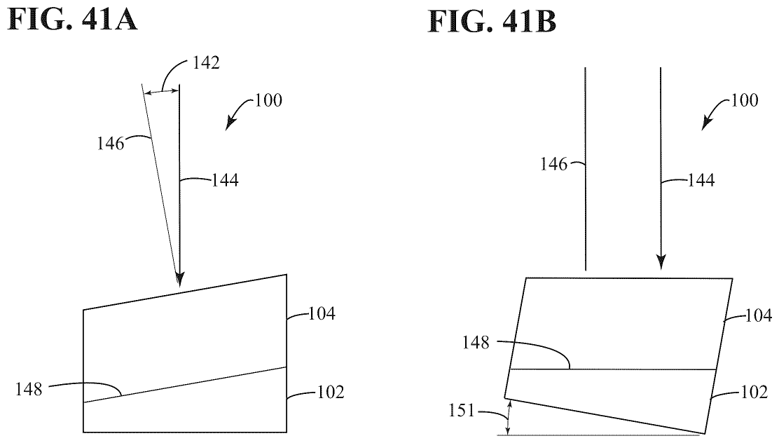

Referring to FIG. 41A, a cross-sectional view is depicted of the MOSFET of any of FIGS. 1-3, illustrating the formation of the substrate layer 102 and epitaxial layer 104 being formed with a predetermined cut angle 142, in order to form a higher quality crystalline lattice in the epitaxial layer 104. During the wafer manufacturing process, boules (e.g., large solid cylindrical masses) of silicon carbide (SIC) are cut into many thin wafers or substrates 102. It has been found that the epitaxial layer 104 that is grown off of the top surfaces 148 of the substrates 102 will have a significantly greater quality crystalline lattice if the top surfaces 148 of the wafers or substrates 102 are cut at a predetermined cut angle 142, which is the angle between a vertical line 144 passing through the surface of the substrate 102 and a line 146 that is normal to the top surface 148 of the substrate 102. The cut angle 142 may be greater than zero degrees. For example, the cut angle 142 may be within a range of 1-15 degrees, or within a range of 2-6 degrees, or may be substantially 4 degrees.

However, the orientation of the 0001 plane (of the well-known Miller Index) of the crystalline lattice of the epitaxial layer 104 will also be tilted at substantially the same cut angle 142 relative to the vertical line 144. Accordingly, the reference line 146 also represents the Miller Index 0001 plane of the crystalline lattice of the epitaxial layer 104 and the 0001 plane's direction or axis.

During a conventional (or random) implantation process, the implantation beam will be directed vertically at the epitaxial layer 104. Accordingly, the reference line 144 also represents the ion implantation beam and its direction of travel. Because in a random implantation process, the ion implantation beam direction 144 and direction of the Miller Index 0001 plane 146 are not aligned, it takes a relatively large amount of implantation energy for the beam to penetrate and implant ions at any particular depth in the epitaxial layer 104.

Referring to FIG. 41B, a cross-sectional view is depicted of the MOSFET of FIG. 41A, wherein the substrate 102 has been tilted to a predetermined tilt angle 151 to align the direction of Miller Index 0001 lattice plane 146 of crystals of the epitaxial layer 104 with the direction of ion implantation beam 144, in order to perform a channeling implantation process on the epitaxial layer 104. More specifically a channeling implantation process is wherein the substrate 102 is tilted by tilt angle 151 to align the Miller Index 0001 lattice plane (as represented by directional arrow 146) and the ion beam (as represented by directional arrow 144), such that the Miller Index 0001 lattice plane and the ion implantation beam are substantially parallel.

Because in a channeling implantation process, the ion implantation beam direction 144 and direction of the Miller Index 0001 plane 146 are substantially aligned, it takes a significantly smaller amount of implantation energy relative to a random implantation process for the beam to penetrate and implant ions at any particular depth in the epitaxial layer 104.

The tilt angle 151 may be greater than zero degrees. For example, the tile angle 150 may be within a range of 1-15 degrees, or within a range of 2-6 degrees, or may be substantially 4 degrees. The tilt angle 151 may also be substantially the same as the cut angle 142.

As will be described herein in greater detail, the use of less implantation energy during channeling implantation (as opposed to random implantation) to form the bottom P-well 114 and the deep P-wells 108 enables the formation of unique features of the bottom P-well 114 that are practically unobtainable through the use of random implantation processes.

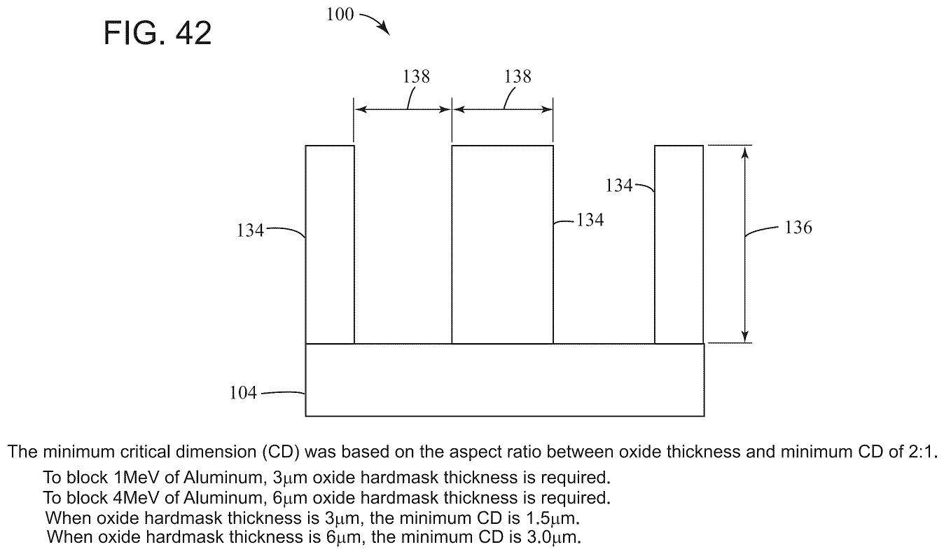

Referring to FIG. 42, a cross-sectional view is depicted of the oxide hardmask 134 disposed over an epitaxial layer 104 of MOSFET 100. FIG. 42 illustrates the minimum critical dimensions (CD) for various implantation energies, based on a fixed aspect ratio between the oxide hardmask depth 136 required at any given energy level and the minimum critical dimension or minimum width 138 of the hardmask opening that would be required for any given etching or implantation process.

During an implantation process, for example in the formation of a bottom P-well 114 in an open trench 132 as illustrated in FIG. 38, a hardmask 134 must be used to protect the underlying structures (e.g., areas of the P-well 106, P-type region 110 and N-source 112 that are covered by the hardmask 134) from damage during the implantation processes. It is important to note that the greater the implantation energy required to implant the bottom P-well 114, the greater the thickness 136 of the hardmask 134 must be in order to provide adequate protection to the underlying structures.

However, the maximum aspect ratio, i.e., the ratio of the thickness 136 of the hardmask 134 to the minimum width (or critical dimension) 138 of the required opening of the hardmask 134, will not change as the thickness 136 increases. Accordingly, the minimum width 138 of the opening will disadvantageously grow as the implantation energy is increased. Moreover, the pitch (or cell pitch) 150 (see FIGS. 43-45) MOSFET 100 will also disadvantageously grow and the number of MOSFET 100 cells that can be placed in a given area will be significantly reduced.

In the illustration of FIG. 42, the critical dimension is based on an aspect ratio of 2 to 1 between the oxide thickness (or depth) 136 and the minimum width 138. It can be seen that:

To block one (1) mega electron volt (MeV) of implantation energy, an oxide hardmask 134 having a depth (or thickness) 136 of 3 microns is required. Therefore, the critical dimension, or minimum width 138 must be 1.5 microns on order to maintain the aspect ratio of 2 to 1.

To block four (4) MeV of implantation energy, an oxide hardmask 134 having a depth (or thickness) 136 of 6 microns is required. Therefore, the critical dimension, or minimum width 138 must be 3.0 microns on order to maintain the aspect ratio of 2 to 1.

Accordingly, as the ion implantation energy rises, so too does the required width 138 and the overall pitch 150 (see FIGS. 43-45). Therefore, because channeling implantation process would require less energy than a random implantation process for the same implantation feature (for example, a bottom P-well or a deep P-well) of a structure (for example, MOSFET 100), the minimum pitch 150 of the structure would inherently be smaller using the channeling implantation process.

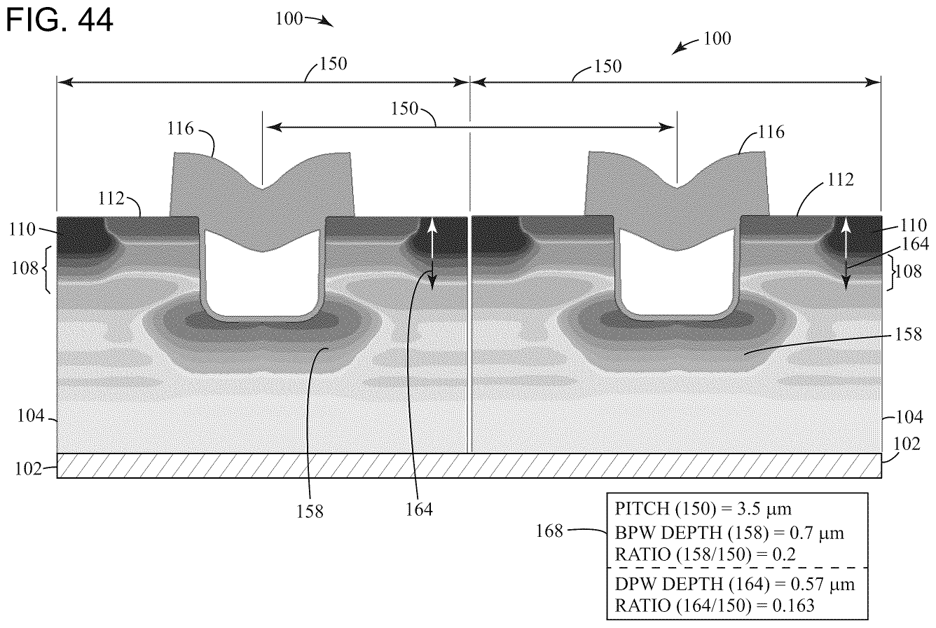

Referring to FIGS. 43, 44 and 45, a cross-sectional view is depicted of the MOSFET 100 of FIG. 3, wherein:
the bottom P-well and the deep P-wells were implanted with 1 MeV implantation energy, using a channeling implantation process (FIG. 43),
the bottom P-well and the deep P-wells were implanted with 1 MeV implantation energy, using a random (or conventional) implantation process (FIG. 44), and
the bottom P-well and the deep P-wells were implanted with 4 MeV implantation energy, using a random (or conventional) implantation process.

Referring more specifically to FIG. 43, the pitch (or cell pitch) 150 of a cell, such as MOSFET 100, is the width of the cell or the center-to-center distance between the cells in a plurality of cells. The bottom P-well 114, as illustrated, is the P-well that extends downward into the epitaxial layer 104 from the bottom surface 152 of the gate 118. The deep P-wells 114 are the P-wells that are disposed on opposing sides of the gate 118 and extend deep into the epitaxial layer. For example, the deep P-wells 108 may extend from the top surface of the MOSFET 100 or from the bottom of the P-type region 110, and may extend deep enough into the epitaxial layer to reach below the bottom surface 152 of the gate 118.

Advantageously, the structure of FIG. 3 (as well as FIGS. 1 and 2) forms a vertical conductive channel (as indicated in circle 154) along the sidewall of the gate 118 (as opposed to a horizontal channel under the gate 118), when the MOSFET 100 is activated. The vertical channel 154 may provide higher channel mobility, higher cell density and may require no JFET region compared to MOSFET structures with horizontal channels.

However, a high electric field may occur at the corners (as indicated in circle 156) of the trench 132, which may impede performance of a MOSFET (such as MOSFET 100) with a vertical channel (such as channel 154). Because the presence of P type material in the proximity of the electric field 156 helps to suppress the electric field 156, the bottom P-well 114 and deep P-wells 108 are formed within the MOSFET 100, as discussed earlier herein.

Advantageously, the bottom P-well 114 covers the corners of the trench 132 and extends deep into the epitaxial layer 104. The greater the depth 158 of the bottom P-well 114 (as measured from the top of the bottom P-well 114 (that is just above the corners of the trench 132) to the bottom of the bottom P-well 114), the better shielding of the corners of the trench 132, which results in a reduced electric field 156 at the corners of the trench 132. So, the ratio between the bottom P-well 114 and the cell pitch (for example, being greater than 0.4) becomes very important for suppressing the electric field.

Also advantageously, the deep P-wells 108 are in close proximity to the to the electric field 156 to also help suppress the electric field 156. However, care must be taken to prevent the bottom P-wells 108 from getting too close to the trench 132 and over narrowing the width 162 of the epitaxial layer 104 between the bottom P-wells 114 and the deep P-wells 108. If the width 162 of the epitaxial layer 104 between the bottom P-well 114 and the deep P-wells 108 becomes to narrow (e.g., less than 3 microns), then a restriction is created in the current flow through the epitaxial layer 104 from the channel 154 to the substrate 102. Accordingly, the width 162 of the epitaxial layer 104 between bottom P-well 114 and deep P-well 108 should be between 3 and 6 microns, or between 3 and 5 microns, or between 3.5 and 4.5 microns, to enable the deep P-well 108 to be close enough to the electric field 156 to suppress the electric field 156 and not to be too close to the bottom P-well 114 to create a current restriction.

The greater the depth 164 of the deep P-well 108 (as measured from the top surface of the MOSFET 100 to the bottom of the bottom P-well 108), the more the deep P-well may suppress the electric field 156. So, for example, the depth 164 of the deep P-well 114 extending into the epitaxial layer below the bottom surface 152 of the trench 132 or the depth 164 of the bottom P-well 108 being greater than the depth 160 of the trench 132, advantageously may significantly help to suppress the electric field 156.

Advantageously, because the deep P-wells 108 and bottom P-well 114 of the MOSFET 100 of FIG. 3 were formed using a channeling implantation process, then the depth 164 of the deep P-wells 108 and the depth 158 of the bottom P-well 114 may be made comparatively large relative to the pitch 150 of the MOSFET 100. As discussed earlier herein, a channeling implantation process is where the substrate layer 102 and epitaxial layer 104 are tilted at a tilt angle 151 (see FIGS. 41A and 41B) to align the Miller Index 0001 lattice plane and the ion implantation beam of the implantation process such that the Miller Index 0001 lattice plane and the ion implantation beam are substantially parallel.

As will be seen in the comparison of FIGS. 43, 44 and 45, the ratio of the bottom P-well depth 158 to the pitch 150 and the ratio of the deep P-well depth 164 to the pitch 150 of MOSFET 100 can be made very large compared to the same ratios using a random (or conventional) implantation process with the same implantation energy. Moreover, the same ratios using a random implantation process may not be able to be made at any commercially available implantation energy.

As can be seen in table 166 of FIG. 43, with an implantation energy of 1 MeV, using a channeling implantation process and setting the cell pitch 150 to 3.5 microns, the depth of the bottom P-well (BPW) 158 reaches 2.5 microns. Accordingly, the ratio of BPW depth to Pitch is 2.5 to 3.5 or 0.714. So, this ratio may be 0.4 or greater, 0.5 or greater, 0.6 or greater, or 0.7 or greater and still be easily commercially available to be made using the methods described herein.

Also, as can be seen in table 166 of FIG. 43, with an implantation energy of 1 MeV, using a channeling implantation process and setting the cell pitch 150 to 3.5 microns, the depth of the deep P-well (DPW) 164 reaches 1.35 microns. Accordingly, the ratio of DPW depth to Pitch is 1.35 to 3.5 or 0.386. So, this ratio may be 2.5 or greater, 3.0 or greater, or 3.5 or greater and still be easily commercially available to be made using the methods described herein.

Referring now to FIG. 44, the basic structure of the MOSFET 100 is similar to the MOSFET 100 of FIG. 43, wherein the cell pitch is set at 3.5 microns, and there are both a bottom P-well 114 and deep P-wells 108. In this case, a 1 MeV implantation energy was used to form the deep P-wells 108 and the bottom P-well 114, however a random implantation process (rather than a channeling implantation process) was used.

As can be seen in table 168 of FIG. 44, with an implantation energy of 1 MeV (i.e., the same implantation energy as used in FIG. 43), using a random implantation process and setting the cell pitch 150 to the same 3.5 microns, the depth of the bottom P-well (BPW) 158 only reaches a mere 0.7 microns. This is less than a third of the BPW depth 158 of 2.5 microns attained in FIG. 43. Accordingly, the ratio of BPW to Pitch is 0.7 to 3.5 or 0.2, which is significantly less than the 0.714 ratio attained in FIG. 43 using the same implantation energy. This ratio of 0.2 is even less than the 0.4 ratio of BPW depth 158 to Pitch 150 that may be attained by using a channeling implantation process at much less implantation energy (e.g., between 200 and 400 KeV).

Also, as can be seen in table 168 of FIG. 44, with an implantation energy of 1 MeV, using a random implantation process and setting the cell pitch 150 to 3.5 microns, the depth of the deep P-well (DPW) 164 only reaches a mere 0.57 microns. This is less than half of the DPW depth 164 of 1.35 microns attained in FIG. 43. Accordingly, the ratio of DPW depth to Pitch is 0.57 to 3.5 or 0.163, which is significantly less than the 0.386 ratio attained in FIG. 43. This ratio of 0.163 is even less than the 0.25 ratio of DPW depth 164 to Pitch 150 that may be attained by using a channeling implantation process at much less implantation energy (e.g., between 200 and 400 KeV).

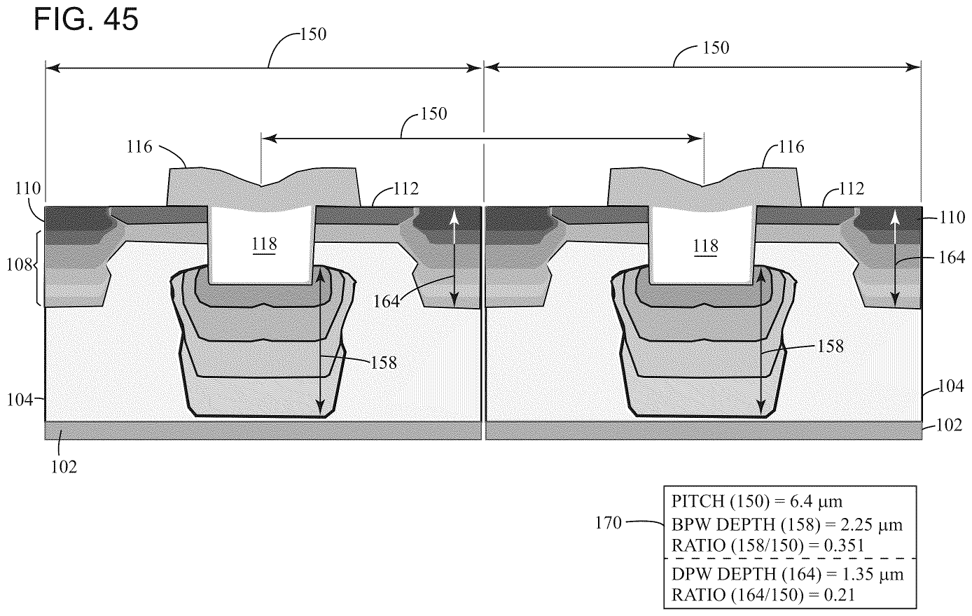

Referring now to FIG. 45, the basic structure of the MOSFET 100 is similar to the MOSFET 100 of FIG. 43, wherein there are both a bottom P-well 114 and deep P-wells 108. In this case however, a 4 MeV implantation energy was used to form the deep P-wells 108 and the bottom P-well 114, and a random implantation process (rather than a channeling implantation process) was used. The 4 MeV implantation energy is about the maximum implantation energy available in the current market using commercially available equipment.

This level of implantation energy was utilized in an effort to obtain a similar bottom P-well depth 158 and deep P-well depth 164 as that of FIG. 43. However, due to the higher implantation energy of 4 MeV in FIG. 45 compared to 1 MeV in FIG. 43, the hard masks used to protect the underlying structures of MOSFET 100 during the random implantation process had to be much thicker than during the channeling implantation process. As explained earlier herein, this forced the cell pitch 150 to increase from 3.5 microns to 6.4 microns.

As can be seen in table 170 of FIG. 45, with an implantation energy of 4 MeV (to attain a roughly similar BPW depth 158 and DPW depth 164 as obtained in FIG. 43), using a random implantation process and having the cell pitch 150 grow to 6.4 microns, the depth of the bottom P-well (BPW) 158 reached 2,25, which was comparably similar to the 2.5 microns obtained in FIG. 43. However, because the cell pitch 150 was forced to grow to 6.4 microns, the ratio of BPW to Pitch is 2.25 to 6.4 or a mere 0.351, which is significantly less than the 0.714 ratio attained in FIG. 43 using the same implantation energy. This ratio of 0.351 is even less than the 0.4 ratio of BPW depth 158 to Pitch 150 that may be attained by using a channeling implantation process at much less implantation energy (e.g., between 200 and 400 KeV).

Also, as can be seen in table 170 of FIG. 45, with an implantation energy of 4 MeV, using a random implantation process and having the cell pitch 150 grow to 6.4 microns, the depth of the deep P-well (DPW) 164 reaches 1.35 microns. This is substantially the same DPW depth 164 attained in FIG. 43. However, because the cell pitch 150 was forced to grow to 6.4 microns, the ratio of DPW to Pitch is 1.35 to 6.4 or a mere 0.21, which is significantly less than the 0.386 ratio attained in FIG. 43 using only 1 MeV of implantation energy. This ratio of 0.21 is even less than the 0.25 ratio of DPW depth 164 to Pitch 150 that may be attained by using a channeling implantation process at much less implantation energy (e.g., between 200 and 400 KeV).

Accordingly, a ratio of bottom P-well depth 158 to cell pitch 150 of 0.4 or greater is virtually unobtainable using a random implantation process, but can be obtained using a channeling implantation process. Also, a ratio of deep P-well depth 164 to cell pitch 150 of 0.25 or greater is virtually unobtainable using a random implantation process, but can be obtained using a channeling implantation process. Advantageously, the ratio of bottom P-well depth 158 to cell pitch 150 of 0.4 or greater and the ratio of deep P-well depth 164 to cell pitch 150 of 0.25 or greater, significantly suppresses the electric field build up at the corners of the trench 132 in MOSFET 100.

The above cell pitches 150, bottom P-well depths 158, deep P-well depths 164, and ratios derived therefrom have been described with reference to the structure of MOSFET 100 of FIG. 3. However, the cell pitches 150, bottom P-well depths 158, deep P-well depths 164 and ratios derived therefrom are also applicable to any MOSFET 100, including the MOSFET 100 described in FIGS. 1 and 2 herein.

It should be appreciated that all combinations of the foregoing concepts and additional concepts discussed in greater detail herein (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

Although the invention has been described by reference to specific examples, it should be understood that numerous changes may be made within the spirit and scope of the inventive concepts described. Accordingly, it is intended that the disclosure not be limited to the described examples, but that it have the full scope defined by the language of the following claims.

1. A field effect transistor, comprising:
a substrate having an upper surface thereof;
an epitaxial layer comprising n-type material disposed over the upper surface of the substrate;
a P-well comprising P-type material diffused within an upper portion of the n-type material of the epitaxial layer;
a first deep P-well comprising P-type material formed within the epitaxial layer, beneath and adjacent to the P-well;
an N-type region disposed at least partially over the P-well;
an oxide region formed within at least a portion of the N-type region, the P-well, and the epitaxial layer, the oxide region further partially disposed over the N-type region; and
a gate formed within the oxide region.

2. The field effect transistor of claim 1, comprising:
the field effect transistor having a cell pitch; and
the first deep P-well having a first deep P-well depth;
wherein a ratio of first deep P-well depth to cell pitch is 0.25 or greater.

3. The field effect transistor of claim 1, comprising:
a second deep P-well comprising P-type material formed in the epitaxial layer beneath and adjacent to the P-well, wherein the first deep P-well and the second deep P-well are positioned on substantially opposite side of the gate.

4. The field effect transistor of claim 3, comprising:
the field effect transistor having a cell pitch; and
the second deep P-well having a second deep P-well depth;
wherein a ratio of second deep P-well depth to cell pitch is 0.25 or greater.

5. The field effect transistor of claim 1, comprising:
at least one P-type region disposed over a portion of the P-well and adjacent to the N-type region.

6. A field effect transistor, comprising:
a substrate having an upper surface thereof;
an epitaxial layer disposed over the upper surface of the substrate;
a bottom P-well formed within a bottom portion of the epitaxial layer;
a P-well disposed over the epitaxial layer and the bottom P-well;
an N-type region disposed at least partially over the P-well;
an oxide region formed within at least a portion of the N-type region, the P-well, the epitaxial layer, and the bottom P-well and partially disposed over the N-type region; and
a gate formed within the oxide region.

7. The field effect transistor of claim 6, wherein the bottom P-well includes at least two distinct areas, each of the distinct areas of the bottom P-well further comprising a respective doping concentration.

8. The field effect transistor of claim 6, wherein a bottom P-well width is greater than the gate.

9. The field effect transistor of claim 6, comprising:
the field effect transistor having a cell pitch; and
the bottom P-well having a bottom P-well depth;
wherein a ratio of bottom P-well depth to cell pitch is 0.4 or greater.

10. A field effect transistor, comprising:
a substrate having an upper surface thereof;
an epitaxial layer disposed over the upper surface of the substrate;
a bottom P-well formed within a bottom portion of the epitaxial layer;
a P-well disposed over the epitaxial layer and the bottom P-well;
an N-type region disposed at least partially over the P-well;
a first deep P-well adjacent to the P-well and the bottom P-well;
an oxide region formed within at least a portion of the N-type region, the P-well, the epitaxial layer, and the bottom P-well and partially disposed over the N-type region; and
a gate formed within the oxide region.

11. The field effect transistor of claim 10, wherein the bottom P-well includes at least two distinct areas, each of the distinct areas of the bottom P-well further comprising a respective doping concentration.

12. The field effect transistor of claim 10, wherein:
the first deep P-well includes at least two distinct areas of the first deep P-well, each of the distinct areas further comprising a respective doping concentration.

13. The field effect transistor of claim 10, comprising:
a second deep P-well adjacent to the P-well and the bottom P-well, wherein the first deep P-well and the second deep P-well are positioned on substantially opposite sides of the gate.

14. The field effect transistor of claim 13, comprising:
the field effect transistor having a cell pitch; and
the second deep P-well having a second deep P-well depth;
wherein a ratio of second deep P-well depth to cell pitch is 0.25 or greater.

15. The field effect transistor of claim 10, comprising:
at least one P-type region disposed over a portion of the P-well and adjacent to the N-type region.

16. The field effect transistor of claim 10, comprising:
the field effect transistor having a cell pitch; and
the first deep P-well having a first deep P-well depth;
wherein a ratio of first deep P-well depth to cell pitch is 0.25 or greater.

17. The field effect transistor of claim 10, comprising:
the field effect transistor having a cell pitch; and
the bottom P-well having a bottom P-well depth;
wherein a ratio of bottom P-well depth to cell pitch is 0.4 or greater.

18. (canceled)

19. (canceled)

20. (canceled)

21. (canceled)

22. (canceled)

23. (canceled)

24. (canceled)

25. (canceled)

26. (canceled)

27. (canceled)
